(19) United States
(12) Patent Application Publication
(10) Pub. No.: US 2025/0266352 A1
(43) Pub. Date: Aug. 21, 2025

(54) SEMICONDUCTOR MEMORY DEVICE

(71) Applicant: Kioxia Corporation, Tokyo (JP)

(72) Inventors: Kouji MATSUO, Ama Aichi (JP); Shunichi SENO, Yokkaichi Mie (JP)

(73) Assignee: Kioxia Corporation, Tokyo (JP)

(21) Appl. No.: 18/822,821

(22) Filed: Sep. 3, 2024

(30) Foreign Application Priority Data
Feb. 19, 2024 (JP) 2024-022982

(51) Int. Cl. H01L 23/528; H10B 12/00

(52) U.S. Cl. CPC H01L 23/5283; H10B 12/30

(57) ABSTRACT

First to third interconnects and a first conductor are aligned in the first direction. A first insulator surrounds the third interconnect, which sandwiches the first insulator with a first semiconductor, which sandwiches a second insulator with the second interconnect. A third insulator surrounds the first conductor. A second conductor in contact with the first semiconductor. A second semiconductor and the first conductor sandwich the third insulator. A fourth insulator extends over the second interconnect and the first and second semiconductors. A third semiconductor sandwiches the fourth insulator with the second interconnect and the first semiconductor. A fourth semiconductor in contact with the third conductor sandwiches the fourth insulator with the second semiconductor.

### CROSS-REFERENCE TO RELATED APPLICATION

This application is based upon and claims the benefit of priority from Japanese Patent Application No. 2024-22982, filed Feb. 19, 2024, the entire contents of which are incorporated herein by reference.

### FIELD

Embodiments described herein relate generally to semiconductor memory devices.

### BACKGROUND

A semiconductor memory device including three-dimensionally arranged memory cells is known. Examples of the semiconductor memory device include a random access memory (RAM). Examples of the memory cells of the RAM includes a memory cell having a structure of a gain cell. A structure of a memory device including memory cells arranged three-dimensionally and having a gain cell structure and a manufacturing method thereof are complicated.

### BRIEF DESCRIPTION OF DRAWINGS

FIG. 1 illustrates functional blocks of a semiconductor memory device according to a first embodiment.

FIG. 2 illustrates components of a memory cell of the semiconductor memory device of the first embodiment and coupling of the components.

FIG. 3 illustrates a structure along an xy plane of a part of the semiconductor memory device of the first embodiment.

FIGS. 4, 5, 6, and 7 illustrate a cross-sectional structure of a part of the semiconductor memory device of the first embodiment.

FIGS. 8, 9, 10, 11, 12, 13, 14, 15, 16, 17, 18, 19, 20, 21, 22, 23, 24, 25, 26, 27, 28, 29, 30, 31, 32, 33, 34, 35, 36, 37, 38, 39, 40, 41, 42, 43, 44, 45, 46, 47, 48, 49, 50, 51, 52, 53, 54, 55, 56, 57, 58, 59, 60, 61, 62, 63, 64, 65, 66, 67, and 68 illustrate a structure during manufacturing steps of a part of the semiconductor memory device of the first embodiment.

FIG. 69 illustrates a structure during manufacturing steps of a part of a semiconductor memory device according to a first modification of the first embodiment.

FIG. 70 illustrates a structure along an xy plane of a part of a semiconductor memory device according to a first modification of the first embodiment.

FIGS. 71, 72, 73, 74, 75, 76, 77, 78, 79, 80, 81, 82, 83, 84, 85, 86, 87, 88, 89, 90, 91, 92, and 93 illustrate a structure during manufacturing steps of a part of a semiconductor memory device according to a second modification of the first embodiment.

### DETAILED DESCRIPTION

In general, according to one embodiment, a semiconductor memory device includes a first interconnect, a second interconnect, a third interconnect, a first conductor, a first insulator, a first semiconductor, a second insulator, a third insulator, a second conductor, a second semiconductor, a fourth insulator, a third semiconductor, a fourth semiconductor, and a third conductor. The first interconnect extends along a first plane including a first axis and a second axis intersecting with the first axis. The first axis extends in a first direction. The second interconnect extends along the first plane and is provided in the first direction from the first interconnect. The third interconnect extends along the first plane and is provided in the first direction from the second interconnect. The first conductor extends along the first plane and is provided in the first direction from the second interconnect. The first insulator surrounds the third interconnect along the first plane and has a portion located between the third interconnect and the second interconnect. The first semiconductor sandwiches the first insulator together with the third interconnect. The second insulator is between the second interconnect and the first semiconductor. The third insulator surrounds the first conductor along the first plane. The second conductor is in contact with the first semiconductor. The second semiconductor sandwiches the third insulator together with the first conductor and is in contact with the second conductor. The fourth insulator extends over the second interconnect, the first semiconductor, and the second semiconductor along the first plane. The third semiconductor is in contact with the first interconnect and including a portion sandwiching the fourth insulator together with the second interconnect and a portion sandwiching the fourth insulator together with the first semiconductor. The fourth semiconductor is in contact with the third semiconductor and sandwiches the fourth insulator together with the second semiconductor. The third conductor is in contact with the fourth semiconductor.

Embodiments will now be described with reference to the figures. In order to distinguish components having substantially the same function and configuration in an embodiment or over different embodiments from each other, an additional numeral or letter may be added to the end of each reference numeral or letter.

The figures are schematic, and the relation between the thickness and the area of a plane of a layer and the ratio of thicknesses of layers may differ from those in actuality. The figures may include components which differ in relations and/or ratios of dimensions in different figures.

Hereinafter, an embodiment will be described using an xyz orthogonal coordinate system. The x axis extends in an X direction. The y axis extends in a Y direction. The z axis extends in a Z direction. A plus direction of a vertical axis in the drawings may be referred to as an upper side, and a minus direction may be referred to as a lower side. A plus direction of a horizontal axis in the drawings may be referred to as a right side, and a minus direction may be referred to as a left side. In addition, a side having larger coordinates on the z axis may be referred to as an upper side, and a side having smaller coordinates may be referred to as a lower side.

### 1. First Embodiment

### 1.1. Structure (Configuration)

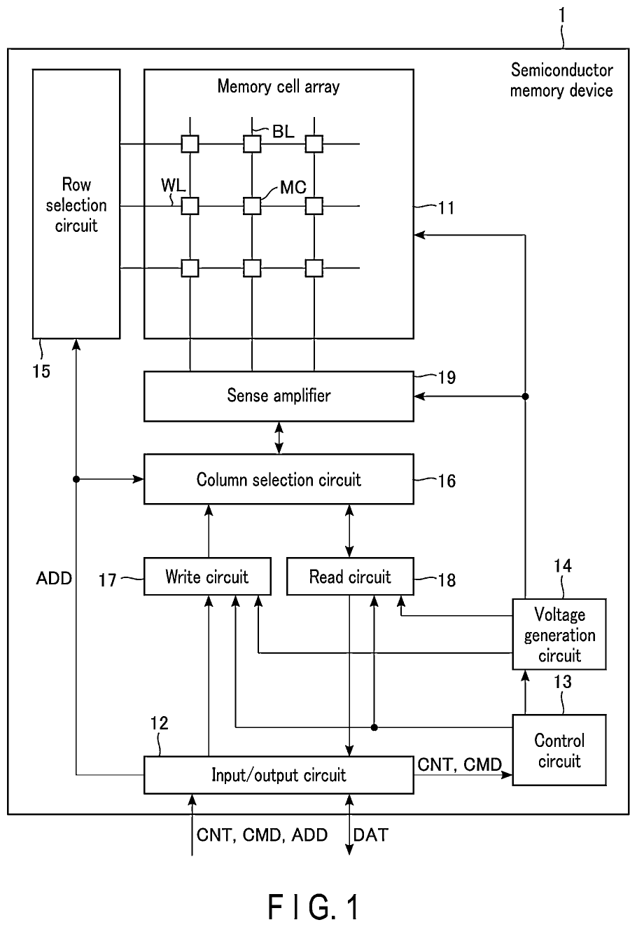

FIG. 1 illustrates functional blocks of a semiconductor memory device according to a first embodiment. The semiconductor memory device 1 is a device that stores data. As illustrated in FIG. 1, the semiconductor memory device 1 includes a memory cell array 11, an input/output circuit 12, a control circuit 13, a voltage generation circuit 14, a row selection circuit 15, a column selection circuit 16, a write circuit 17, a read circuit 18, and a sense amplifier 19.

The memory cell array 11 includes a plurality of memory cells MC, a plurality of word lines WL, and a plurality of bit lines BL. Each memory cell MC can store 1-bit data. Each memory cell MC is coupled to one bit line BL and one word line WL. The memory cell MC is coupled between the bit line BL and a source line (not illustrated). The word line WL is associated with a row. The bit line BL is associated with a column. One memory cell MC is specified by selection of one row and selection of one column.

The input/output circuit 12 is a circuit that inputs and outputs data and signals. The input/output circuit 12 receives a control signal CNT, a command CMD, an address signal ADD, and data DAT from the outside of the semiconductor memory device 1.

The control circuit 13 is a circuit that controls operation of the semiconductor memory device 1. The control circuit 13 receives the command CMD and the control signal CNT from the input/output circuit 12. The control circuit 13 controls the write circuit 17 and the read circuit 18 based on the control instructed by the command CMD and the control signal CNT.

The voltage generation circuit 14 is a circuit that generates various voltages to be used in the semiconductor memory device 1. The voltage generation circuit 14 generates a plurality of voltages having different magnitudes under control of the control circuit 13. The voltage generation circuit 14 supplies the generated voltages to the memory cell array 11, the write circuit 17, the read circuit 18, and the sense amplifier 19.

The row selection circuit 15 is a circuit that selects a row of the memory cell MC. The row selection circuit 15 receives the address signal ADD from the input/output circuit 12. The row selection circuit 15 uses a voltage received from the voltage generation circuit 14 to place one word line WL associated with the row identified by the received address signal ADD in a selected state.

The column selection circuit 16 is a circuit that selects a column of the memory cell MC. The column selection circuit 16 receives the address signal ADD from the input/output circuit 12. The column selection circuit 16 uses the voltage received from the voltage generation circuit 14 to place the bit line BL associated with the column identified by the received address signal ADD in a selected state.

The write circuit 17 is a circuit that performs control for writing data to the memory cells MC. The write circuit 17 receives data to be written from the input/output circuit 12. The write circuit 17 supplies the voltage received from the voltage generation circuit 14 to the column selection circuit 16 based on control and data of the control circuit 13.

The read circuit 18 is a circuit that performs control for reading data from the memory cells MC. The read circuit 18 supplies the voltage received from the voltage generation circuit 14 to the column selection circuit 16 under the control of the control circuit 13. The read circuit 18 supplies a plurality of control signals for data reading to the sense amplifier 19.

The sense amplifier 19 is a circuit for determining data stored in the memory cell MC. The sense amplifier 19 includes a plurality of sense amplifier circuits. The sense amplifier 19 receives a plurality of voltages from the voltage generation circuit 14 and operates using the received voltages. The sense amplifier 19 amplifies the potential on the bit line BL in order to determine the data stored in the memory cell MC of the data reading target during the data reading. The determined data is supplied to the input/output circuit 12.

### 1.1.1. Memory Cell

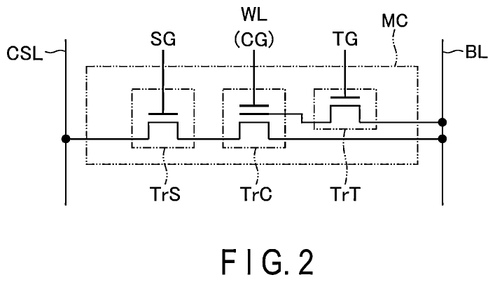

FIG. 2 illustrates components of a memory cell of the semiconductor memory device of the first embodiment and coupling of the components. Hereinafter, one of the source and the drain of the transistor may be referred to as one end of the transistor, and the other may be referred to as the other end of the transistor.

As illustrated in FIG. 2, the memory cell MC has a structure of a gain cell. That is, the memory cell MC includes a p-type metal oxide semiconductor field effect transistor (MOSFET) TrS, a p-type floating gate MOSFET TrC, and an n-type MOSFET TG.

The transistor TrS is coupled to one source line CSL at one end. The transistor TrS is coupled to an interconnect SG at the gate.

The transistor TrC includes a floating gate insulated from the surroundings. The transistor TrC is coupled to the other end of the transistor TrS at one end. The transistor TrC is coupled to the bit line BL at the other end. The transistor TrC is coupled to an interconnect CG at a control gate. The interconnect CG is coupled to one word line WL.

The transistor TrT is coupled to the floating gate of the transistor TrC at one end. The transistor TrT is coupled to the bit line BL at the other end. The transistor TrT is coupled to an interconnect TG at a gate.

### 1.1.2. Memory Cell Array

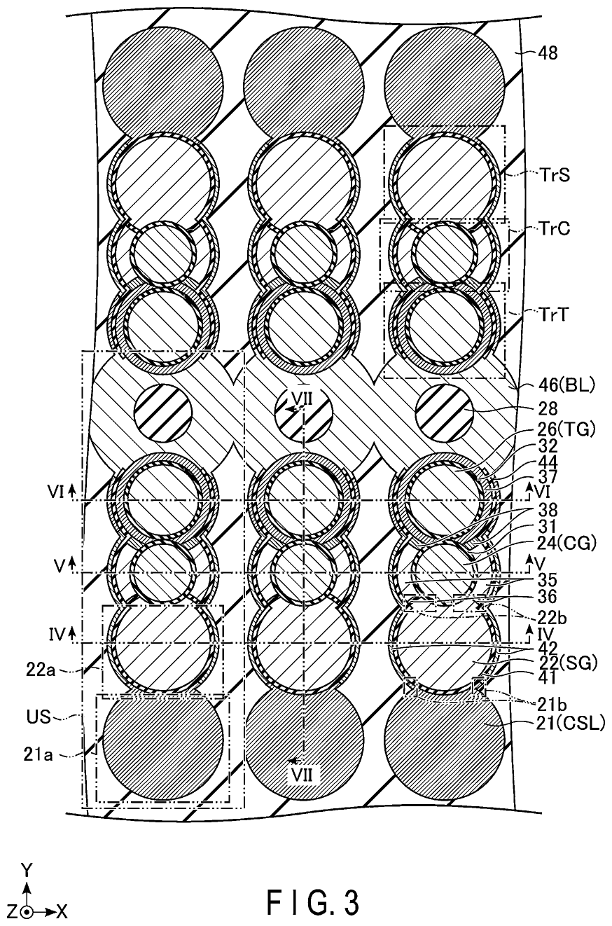

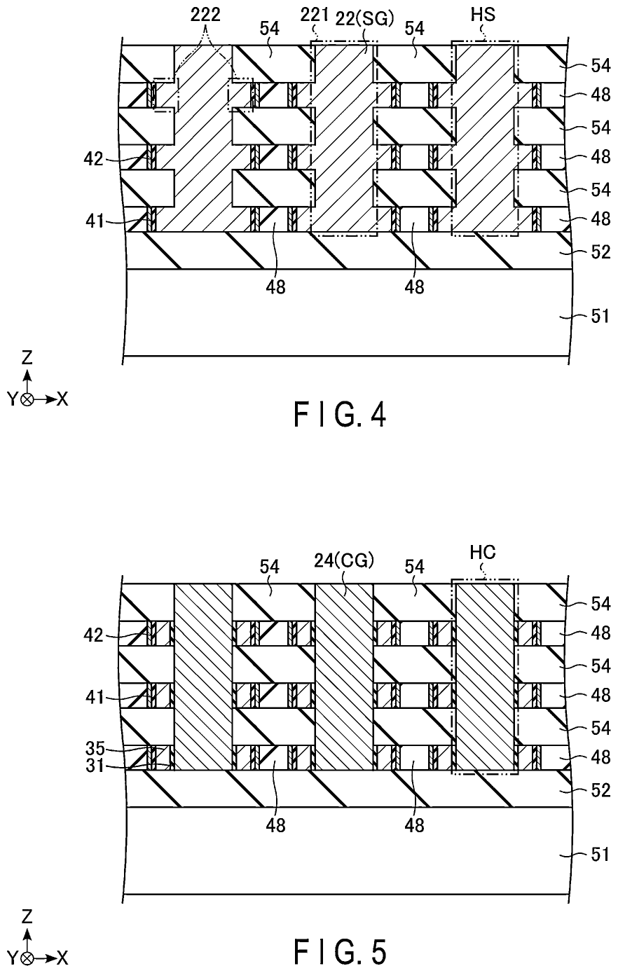

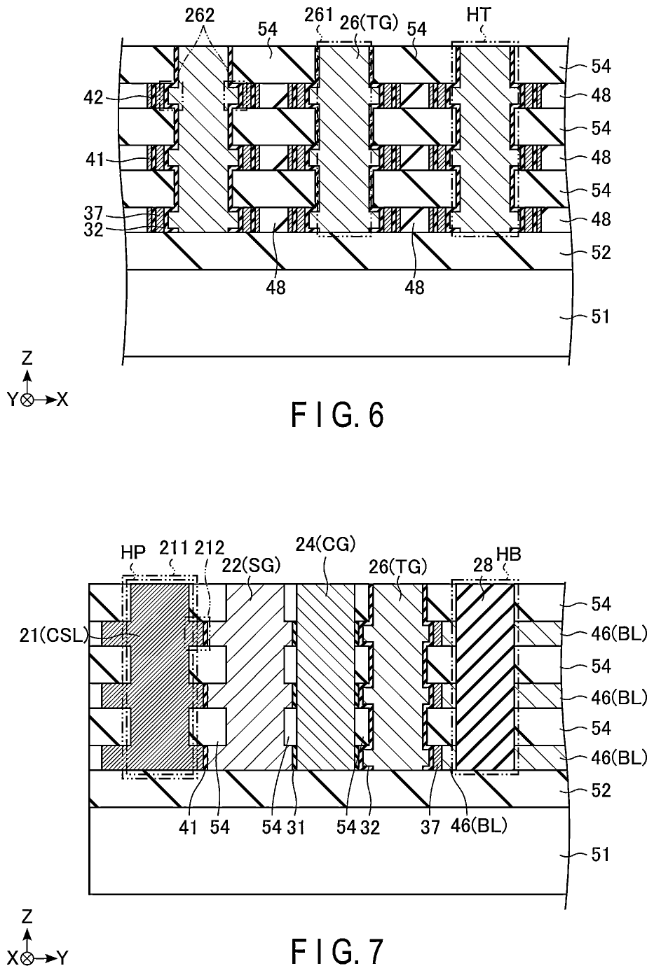

FIG. 3 illustrates a structure along an xy plane of a part of the semiconductor memory device of the first embodiment. FIGS. 4 to 7 illustrate a cross-sectional structure of a part of the semiconductor memory device of the first embodiment. FIG. 4 illustrates a structure along line IV-IV in FIG. 3 and a structure along an xz plane. FIG. 5 illustrates a structure along line V-V in FIG. 3 and a structure along the xz plane. FIG. 6 illustrates a structure along line VI-VI in FIG. 3 and a structure along the xz plane. FIG. 7 illustrates a structure along line VII-VII in FIG. 3 and a structure along a yz plane.

As illustrated in FIG. 3, the semiconductor memory device 1 includes a plurality of unit structures US. Each unit structure US functions as one memory cell MC. The unit structures US extend in the Y direction and are arranged in the X direction. Further, the two unit structures US arranged in the Y direction have a symmetrical structure with respect to the x axis and share a part of the structure. Hereinafter, the lower unit structure US among the unit structures US arranged in the Y direction will be described. Each unit structure US includes semiconductors 21, 22, 24, 35, 37, 42, and 44, conductors 26, 38, and 46, and insulators 28, 31, 32, 36, and 41. The semiconductor memory device 1 further includes an insulator 48.

In each unit structure US, the semiconductors 21, 22, and 24, the conductors 25 and 26, and the insulator 28 are arranged in the Y direction.

The semiconductor 21 extends along the xy plane. In one example, the semiconductor 21 has a shape based on a circle or an ellipse along the xy plane. The semiconductor 21 includes one first portion 21a and two second portions 21b. The first portion 21a has a shape in which a part of an upper side of the circle or the ellipse is missing. Thus, the shape of a lower half and the shape of an upper half of the first portion 21a are different. An upper end of the first portion 21a has a contour along the contour of the semiconductor 22. In one example, the semiconductor 21 includes silicon. The semiconductor 21 is doped with impurities and has conductivity. In one example, the semiconductor 21 contains p-type impurities. Examples of the p-type impurities include boron. The semiconductor 21 functions as an interconnect and functions as at least a part of the source line CSL.

A conductor may be provided instead of the semiconductor 21. In one example, the conductor includes titanium nitride. Alternatively, instead of the semiconductor 22, a conductor at the center and a semiconductor that is located on a side surface of the conductor and doped with p-type impurities may be provided. Examples of the p-type impurities include boron.

Each of the second portions 21b is coupled to the upper end of the first portion 21a on a lower side and is continuous with the first portion 21a. The second portions 21b each have a shape along the contour of the semiconductor 22 and extend along the semiconductor 22. The second portions 21b are spaced from each other.

The semiconductor 22 extends along the xy plane. In one example, the semiconductor 22 has a shape based on a circle or an ellipse along the xy plane. The semiconductor 22 includes one first portion 22a and two second portions 22b. The first portion 22a has a shape in which a part of the upper side of a circle or an ellipse is missing. Thus, the shape of a lower half and the shape of an upper half of the first portion 22a are different. An upper end of the first portion 22a has a contour along the contour of the semiconductor 24. A lower end of the first portion 22a is located between the second portions 21b of the semiconductor 21. In one example, the semiconductor 22 includes silicon. The semiconductor 22 is doped with impurities and has conductivity. In one example, the semiconductor 22 contains p-type impurities. Examples of the p-type impurities include boron. The semiconductor 22 functions as at least a part of the interconnect SG. In another example, the semiconductor 22 contains n-type impurities. Examples of the n-type impurities include arsenic.

A conductor may be provided instead of the semiconductor 22. In one example, the conductor includes titanium nitride. Alternatively, instead of the semiconductor 22, a conductor at the center and a semiconductor that is located on a side surface of the conductor and doped with impurities may be provided. Similarly to the semiconductor 22, the impurities may be n-type or p-type.

The second portion 22b is coupled to the upper end of the first portion 22a at a lower side, and is continuous with the first portion 22a. The second portion 22b is curved. The second portion 22b has a curvature larger than the radius of the first portion 22a. The second portions 21b are spaced from each other.

The semiconductor 24 extends along the xy plane. The semiconductor 24 functions as at least a part of the interconnect CG. In one example, the semiconductor 24 has a circular or elliptical shape. A lower end of the semiconductor 24 is located between the second portions 22b of the semiconductor 22. In one example, the semiconductor 24 includes silicon. The semiconductor 24 is doped with impurities and has conductivity. In one example, the semiconductor 24 contains p-type impurities. Examples of the p-type impurities include boron. In another example, the semiconductor 24 contains n-type impurities. Examples of the n-type impurities include arsenic.

A conductor may be provided instead of the semiconductor 24. In one example, the conductor includes titanium nitride. Alternatively, instead of the semiconductor 24, a conductor at the center and a semiconductor that is located on a side surface of the conductor and doped with impurities may be provided. Similarly to the semiconductor 24, the impurities may be n-type or p-type.

The conductor 26 extends along the xy plane. In one example, the conductor 26 has a circular or elliptical shape along the xy plane. In one example, the conductor 26 includes titanium nitride. The conductor 26 functions as at least a part of the interconnect TG.

The insulator 28 extends along the xy plane. In one example, the insulator 28 has a circular or elliptical shape along the xy plane. In one example, the insulator 28 includes silicon oxide.

The insulator 31 surrounds the semiconductor 24 along the xy plane and extends along the contour of the semiconductor 24. The insulator 31 extends over a surface of the semiconductor 24 along the xy plane. The insulator 31 has an annular shape along the xy plane. The insulator 31 has a radius or curvature larger than the radius of the semiconductor 24 along the xy plane. In one example, the insulator 31 includes silicon oxide. The insulator 31 functions as a block insulator of the transistor TrT. The insulator 31 has a thickness capable of preventing electrons accumulated in the semiconductor 35 from coming off through the insulator 31. In one example, the insulator 31 has a thickness equal to or more than 6 nm.

The insulator 32 surrounds the conductor 26 along the xy plane and extends along the contour of the conductor 26. The insulator 32 extends over a surface of the conductor 26 along the xy plane. The insulator 32 has a radius or curvature larger than the radius of the conductor 26 along the xy plane. The insulator 32 has an annular shape along the xy plane. In one example, the insulator 32 includes silicon oxide. The insulator 32 functions as a gate insulator of the transistor TrT.

The semiconductor 35 extends along the contour of the insulator 31 on the right side or the left side of the insulator 31. The semiconductor 35 is curved along the contour of the semiconductor 24. The semiconductor 35 extends over a surface of the insulator 31 along the xy plane. The semiconductor 35 has a curvature larger than the radius or curvature of each of the semiconductor 24 and the insulator 31 along the xy plane. The semiconductor 35 covers a part of the insulator 31. A set of two semiconductors 35 in contact with each insulator 31 does not cover a lower end and an upper end of the insulator 31. In one example, the semiconductor 35 includes silicon. The semiconductor 35 functions as the floating gate of the transistor TrC.

The insulator 36 is located between the semiconductor 22 and the semiconductor 35. The insulator 36 is in contact with the semiconductor 22, the semiconductor 35, and the insulator 31. The insulator 36 has a shape along the contour of the second portion 22b of the semiconductor 22. The insulator 36 has a curvature larger than the radius of the first portion 22a and the curvature of the second portion 22b of the semiconductor 22. The insulator 36 covers a surface of the second portion 22b of the semiconductor 22 facing the semiconductor 35 and insulates the semiconductor 22 from the semiconductor 35. In one example, the insulator 36 includes silicon oxide.

The semiconductor 37 extends along the contour of the insulator 32 along the xy plane. The semiconductor 37 partially surrounds the insulator 32. The semiconductor 37 is curved along the contour of the conductor 26. In one example, the semiconductor 37 has an annular shape having a portion opened at a lower end. The semiconductor 37 is in contact with the insulator 31. In one example, the semiconductor 37 is in contact with the insulator 31 at the opening portion. The semiconductor 37 includes a material having a high energy band gap. In one example, the semiconductor 37 includes a material having an energy band gap equal to or more than 2.0 eV. In one example, the semiconductor 37 includes a titanium oxide semiconductor. In another example, the semiconductor 37 includes a semiconductor that includes a set of indium (In), gallium (Ga), zinc (Zn), and oxygen (O). When the semiconductor 37 is a titanium oxide semiconductor or a metal oxide semiconductor of a combination of indium, gallium, zinc, and oxygen, leakage of charges accumulated in the semiconductor 35 to the semiconductor 35 can be suppressed. The semiconductor 37 functions as a channel of the transistor TrT.

The conductor 38 is located between the semiconductor 35 and the semiconductor 37. The conductor 38 is in contact with the semiconductor 35, the semiconductor 37, and the insulator 31. The conductor 38 has a shape along the contour of the semiconductor 37. The conductor 38 is curved. The conductor 38 has a curvature larger than the radius of the conductor 26, the radius of the insulator 32, and the radius (or curvature) of the semiconductor 37. In one example, the conductor 38 includes titanium nitride.

The insulator 41 extends along the semiconductor 22, the insulator 36, the semiconductor 35, the conductor 38, and the semiconductor 37 along the xy plane. The insulator 41 is in contact with the semiconductor 22, the insulator 36, the semiconductor 35, the conductor 38, and the semiconductor 37. The insulator 41 covers surfaces of the semiconductor 22, the insulator 36, the semiconductor 35, the conductor 38, and the semiconductor 37.

The insulator 41 is curved. The insulator 41 has a shape along the contour of the semiconductor 22 in a portion around the semiconductor 22. The insulator 41 has a curvature larger than the radius or curvature of the semiconductor 22 in the portion around the semiconductor 22.

The insulator 41 has a shape along the contour of the semiconductor 35 in a portion around the semiconductor 35. The insulator 41 has a curvature larger than the radius or curvature of the semiconductor 35 in a portion around the semiconductor 35.

The insulator 41 has a shape along the contour of the semiconductor 37 in a portion around the semiconductor 37. The insulator 41 has a curvature larger than the radius or curvature of the semiconductor 37 in the portion around the semiconductor 37.

The insulator 41 has an annular shape opened at the upper end. The insulator 41 does not cover the semiconductor 37 in the opening.

In one example, the insulator 41 includes silicon oxide. The insulator 41 has a thickness capable of preventing electrons accumulated in the semiconductor 35 from coming off through the insulator 41. In one example, the insulator 41 has a thickness equal to or more than of 6 nm. The insulator 41 functions as a gate insulator of the transistor TrS in the portion around the semiconductor 22. Further, the insulator 41 electrically insulates the semiconductor 37 and the semiconductor 44 in the portion around the semiconductor 37.

The semiconductor 42 extends along a part of the insulator 41 along the xy plane. The semiconductor 42 is in contact with the insulator 41. The semiconductor 42 covers the entire portion of the insulator 41 on sides of the semiconductor 22 (that is, a right side and a left side). The semiconductor 42 does not cover a lower end portion of the insulator 41. The semiconductor 42 covers the entire portion of the insulator 41 on sides of the semiconductor 24 (that is, a right side and a left side). The semiconductor 42 covers a portion of the insulator 41 below portions on sides (that is, a right side and a left side) of the semiconductor 37.

The semiconductor 42 is curved. The semiconductor 42 has a shape along the contour of the semiconductor 22 in the portion around the semiconductor 22. The semiconductor 42 has a curvature larger than the radius or curvature of the semiconductor 22 in the portion around the semiconductor 22.

The semiconductor 42 has a shape along the contour of the semiconductor 35 in the portion around the semiconductor 35. The semiconductor 42 has a curvature larger than the radius or curvature of the semiconductor 35 in the portion around the semiconductor 35.

The semiconductor 42 has a shape along the contour of the semiconductor 37 in the portion around the semiconductor 37. The semiconductor 42 has a curvature larger than the radius or curvature of the semiconductor 37 in the portion around the semiconductor 37.

The semiconductor 42 is in contact with the semiconductor 21 and is in contact with the second portion 21b of the semiconductor 21. The semiconductor 42 includes silicon in one example. The semiconductor 42 functions as a channel of the transistor TrS in the portion around the semiconductor 22. The semiconductor 42 functions as a channel of the transistor TrC in the portion around the semiconductor 35.

The semiconductor 44 extends along a part of the insulator 41 along the xy plane. The semiconductor 44 is in contact with the insulator 41. The semiconductor 44 covers a part of the insulator 41 on sides (that is, a right side and a left side) of the conductor 26. The semiconductor 44 covers a portion of the insulator 41 on the sides of the conductor 26, the portion not being covered with the semiconductor 42. The semiconductor 44 has a shape along the contour of the semiconductor 37. The semiconductor 44 has a curvature larger than the radius or curvature of the semiconductor 37. The semiconductor 44 does not cover an uppermost portion of the insulator 41 at an uppermost portion. The semiconductor 44 is deposited by a step different from that of the semiconductor 42 as described later, and thus can have properties different from those of the semiconductor 42. Examples of the properties include density and impurity concentration. The semiconductor 44 includes silicon in one example. The semiconductor 44 is doped with impurities and has conductivity. In one example, the semiconductor 44 contains p-type impurities. Examples of the p-type impurities include boron. In one example, the semiconductor 42 includes silicon containing boron. The semiconductor 44 functions as an interconnect coupling the bit line BL and the source or drain of the transistor TrT.

The conductor 46 extends in the X direction. The conductor 46 surrounds the insulator 28. The conductor 46 has a shape in which a plurality of circles or ellipses lacking an uppermost portion and a lowermost portion is joined in the X direction. The conductor 46 is in contact with the semiconductor 37 at a lower end and an upper end. The conductor 46 is in contact with the semiconductor 44 at a lower end and an upper end. In one example, the conductor 46 includes titanium nitride. The conductor 46 is shared by two unit structures US arranged in the Y direction.

The insulator 48 fills regions where the semiconductors 21, 22, 24, 35, 37, 42, and 44, the conductors 26, 38, and 46, and the insulators 28, 31, 32, 36, and 41 are not provided. In one example, the insulator 48 includes silicon nitride.

A set of the semiconductor 22, the portion of the insulator 41 covering the semiconductor 22, and the portion of the semiconductor 42 on the sides of the semiconductor 22 functions as one transistor TrS. The portion of the semiconductor 42 functions as the channel of the transistor TrS. The portion of the insulator 41 functions as the gate insulator of the transistor TrS.

A set of the semiconductor 24, the portion of the insulator 31 on the sides of the semiconductor 24, the semiconductor 35, the portion of the insulator 41 on the sides of the semiconductor 24, and the portion of the semiconductor 42 on the sides of the semiconductor 24 functions as one transistor TrC. The portion of the insulator 31 functions as a block insulator of the transistor TrC. The semiconductor 35 functions as the floating gate of the transistor TrC. The portion of the insulator 41 on the sides of the semiconductor 24 functions as a tunnel insulator of the transistor TrC. The portion of the semiconductor 42 on the sides of the semiconductor 24 functions as a channel of the transistor TrC.

A set of the conductor 26, the portion of the insulator 32 on the sides of the conductor 26, and the portion of the semiconductor 37 on the sides of the conductor 26 functions as one transistor TrG. The portion of the semiconductor 37 functions as the channel of the transistor TrT. The portion of the insulator 32 functions as the gate insulator of the transistor TrT.

As illustrated in FIGS. 4 to 7, the structure illustrated in FIG. 3 is repeatedly provided in the Z direction. The semiconductor memory device 1 further includes a substrate 51 and insulators 52 and 54.

The substrate 51 extends along the xy plane. In one example, the substrate 51 includes silicon.

The insulator 52 is located on an upper surface of the substrate 51. In one example, the insulator 52 includes silicon oxide.

The insulator 54 extends along the xy plane. In one example, the insulator 54 includes silicon oxide. The layer in which the insulator 54 is located and the layer in which the structure illustrated in FIG. 3 is located are alternately located one by one on an upper surface of the insulator 52. Hereinafter, the layer in which the structure illustrated in FIG. 3 is located may be referred to as a layer in which the memory cell MC is located. FIGS. 4 to 7 illustrate three sets of a layer in which the insulator 54 is located and a layer in which the memory cell MC is located as an example. The semiconductor memory device 1 includes holes HP, HS, HC, HT, and HB.

As illustrated in FIGS. 4 and 7, a hole HS extends in the Z direction. A hole HC is filled with the semiconductor 22. The portion of the semiconductor 22 in the hole HC may be hereinafter referred to as a center portion 221. A portion of the semiconductor 22 other than the center portion 221 may be referred to as a protrusion 222. The protrusion 222 surrounds the center portion 221 along the xy plane. The protrusion 222 protrudes from the center portion 221 in a direction away from the center portion 221. The protrusion 222 is connected to the center portion 221 and is continuous with the center portion 221. The protrusion 222 is located in the layer where the memory cell MC is located. The protrusion 222 is positioned between the insulators 54 arranged in the Z direction. The protrusions 222 located in different layers are connected by the center portion 221. The protrusion 222 is in contact with the insulator 41 and the insulator 31. The first portion 22a illustrated in FIG. 3 includes the center portion 221 and the protrusion 222. The second portion 22b illustrated in FIG. 3 includes the protrusion 222.

As illustrated in FIGS. 5 and 7, a hole HC extends in the Z direction. The hole HC is filled with the semiconductor 24.

As illustrated in FIGS. 6 and 7, a hole HT extends in the Z direction. The hole HT is filled with a part of the conductor 26. The portion of the conductor 26 in the hole HT may be hereinafter referred to as a center portion 261. A portion of the conductor 26 other than the center portion 261 may be referred to as a protrusion 262. The protrusion 262 surrounds the center portion 261 along the xy plane. The protrusion 262 protrudes from the center portion 261 in a direction away from the center portion 261. The protrusion 262 is connected to the center portion 261 and is continuous with the center portion 261. The protrusion 262 is located in the layer where the memory cell MC is located. The protrusion 262 is positioned between the insulators 54 arranged in the Z direction. The protrusions 262 located in different layers are connected by the center portion 261. The protrusion 262 is in contact with the insulator 32.

The insulator 32 covers the surface of the conductor 26 along the z axis.

As illustrated in FIG. 7, a hole HP extends in the Z direction. The hole HP is filled with a part of the semiconductor 21. The portion of the semiconductor 21 in the hole HP may be hereinafter referred to as a center portion 211. A portion of the semiconductor 21 other than the center portion 211 may be referred to as a protrusion 212. The protrusion 212 surrounds the center portion 211 along the xy plane. The protrusion 212 protrudes from the center portion 211 in a direction away from the center portion 211. The protrusion 212 is connected to the center portion 211 and is continuous with the center portion 211. The protrusion 212 is located in the layer where the memory cell MC is located. The protrusion 212 is positioned between the insulators 54 arranged in the Z direction. The protrusions 212 located in different layers are connected by the center portion 211. The protrusion 212 is in contact with the insulator 41.

A hole HB extends in the Z direction. The hole HB is filled with the insulator 28.

### 1.2. Manufacturing Method

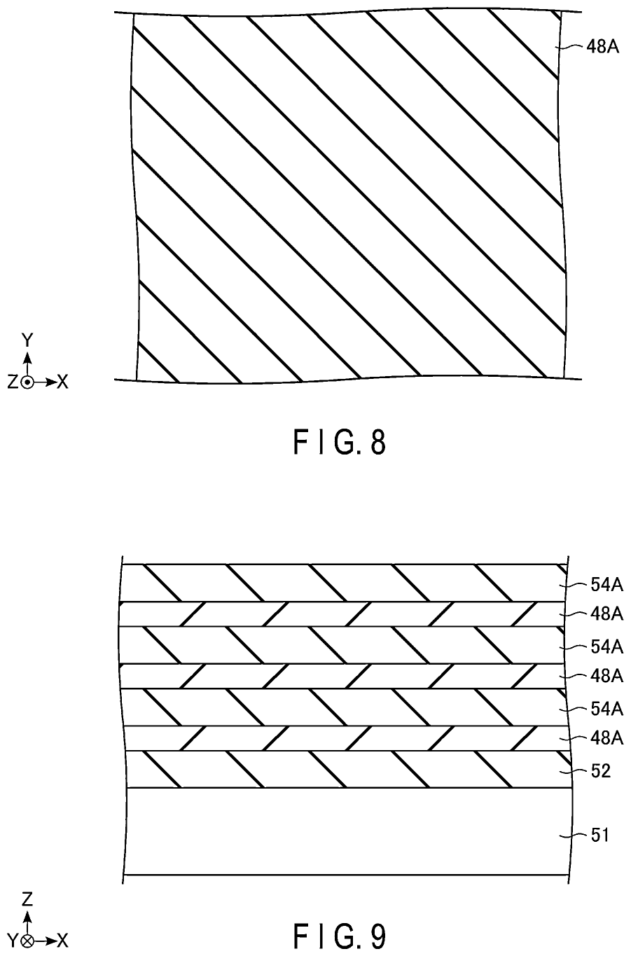

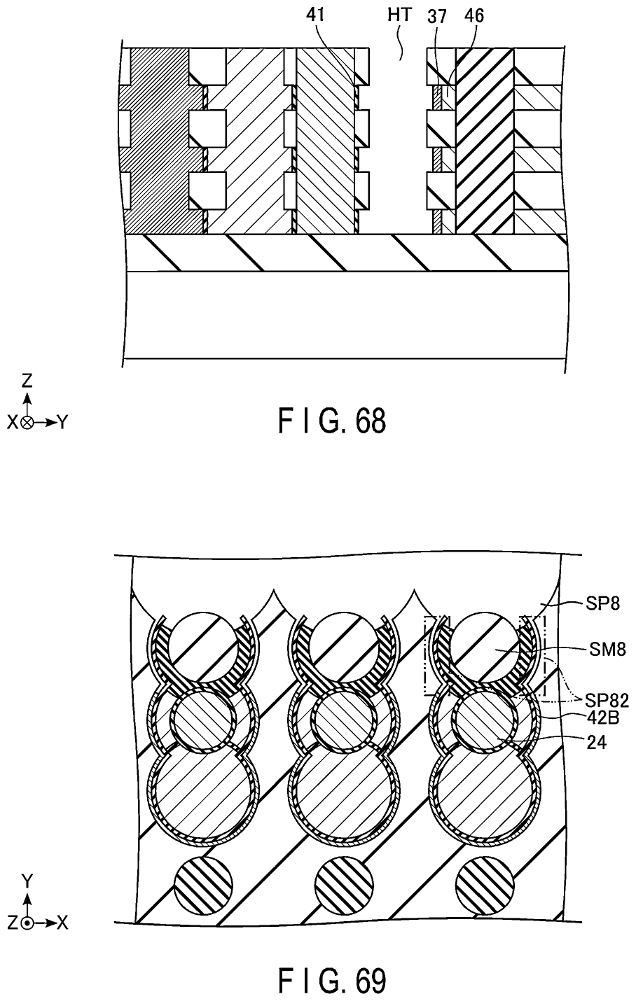

FIGS. 8 to 68 illustrate examples of a structure during manufacturing steps of a part of the semiconductor memory device according to the first embodiment.

FIG. 8 illustrates a portion of the region illustrated in FIG. 3. FIG. 9 illustrates the region illustrated in FIG. 4.

As illustrated in FIGS. 8 and 9, the insulator 52 is formed on the upper surface of the substrate 51. Next, on the upper surface of the insulator 52, an insulator 48A and an insulator 54A are alternately deposited one by one. The insulator 48A is a component to be shaped into the insulator 48 by a later step. The insulator 54A is a component to be shaped into the insulator 54 by a later step.

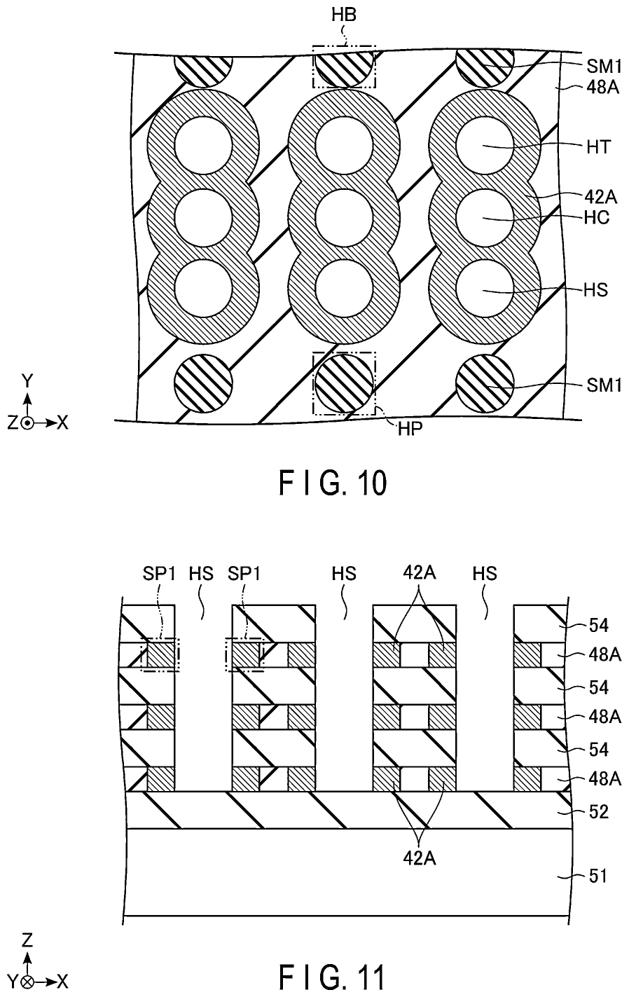

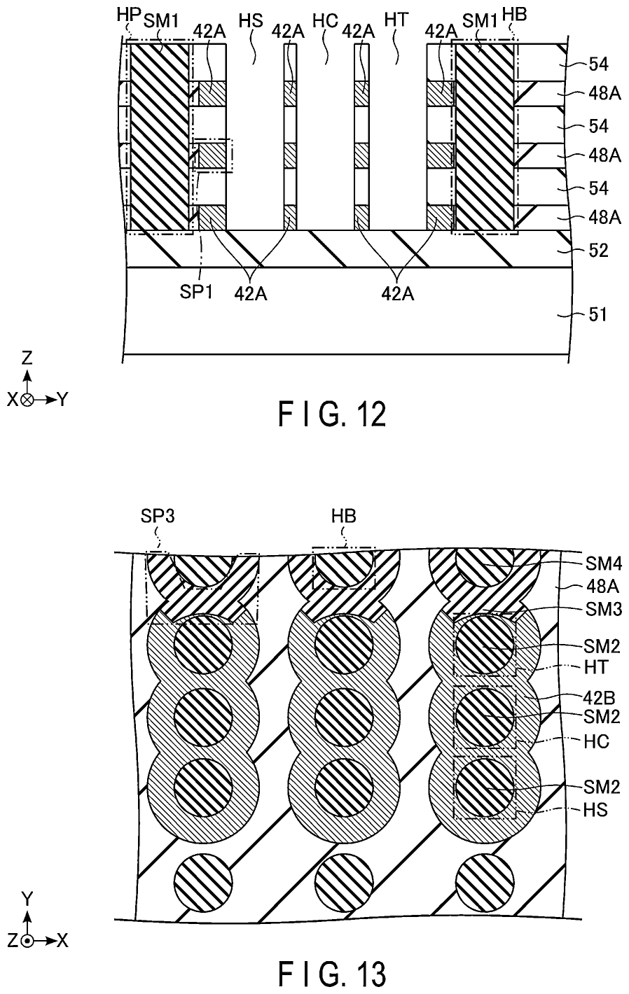

FIG. 10 illustrates a portion of the region illustrated in FIG. 3. FIG. 11 illustrates the region illustrated in FIG. 4. FIG. 12 illustrates the region illustrated in FIG. 7.

As illustrated in FIGS. 10 to 12, the holes HP, HS, HC, HT, and HB are formed in the insulators 54A and 48A. Examples of forming methods includes a set of a lithography process and reactive ion etching (RIE). The holes HP, HS, HC, HT, and HB penetrate the insulators 54A and 48A and extend in the Z direction. By forming the holes HS, HC, HT, and HB, the insulator 54A becomes the insulator 54.

The holes HP, HS, HC, HT, and HB are filled with a sacrificial material SM1. In one example, the sacrificial material SM1 includes silicon oxide and (or) polysilicon. The sacrificial material SM1 may include polysilicon and silicon oxide covering the polysilicon. Examples of filling methods include chemical vapor deposition (CVD).

The sacrificial material SM1 in the holes HS, HC, and HT is removed. Examples of removal methods include a set of a lithographic process and RIE. That is, a mask having openings is formed on an upper surface of a structure obtained by the steps so far by the lithographic process. The mask has openings above the holes HS, HC, and HT. Next, the sacrificial material SM1 below the openings is removed by the RIE using the mask. Subsequent steps involving removal of one or more of sacrificial materials similar to the sacrificial material SM1 in the holes HP, HS, HC, HT, and HB are also performed in a similar manner.

Portions of the insulator 48A exposed in the holes HS, HC, and HT are removed. Examples of removal methods include wet etching. By the removal, spaces SP1 are formed around the holes HS, HC, and HT in the insulator 48A (that is, the layer in which the memory cell MC is located). The spaces SP1 have an annular shape surrounding the holes HS, HC, and HT.

A semiconductor 42A is formed in the spaces SP1. The semiconductor 42A is a component to be shaped into the semiconductor 42 in a later step. Examples of forming methods include CVD.

In the process of forming the semiconductor 42A, the semiconductor 42A formed in the holes HS, HC, and HT is removed. Thus, the holes HS, HC, and HT are formed again.

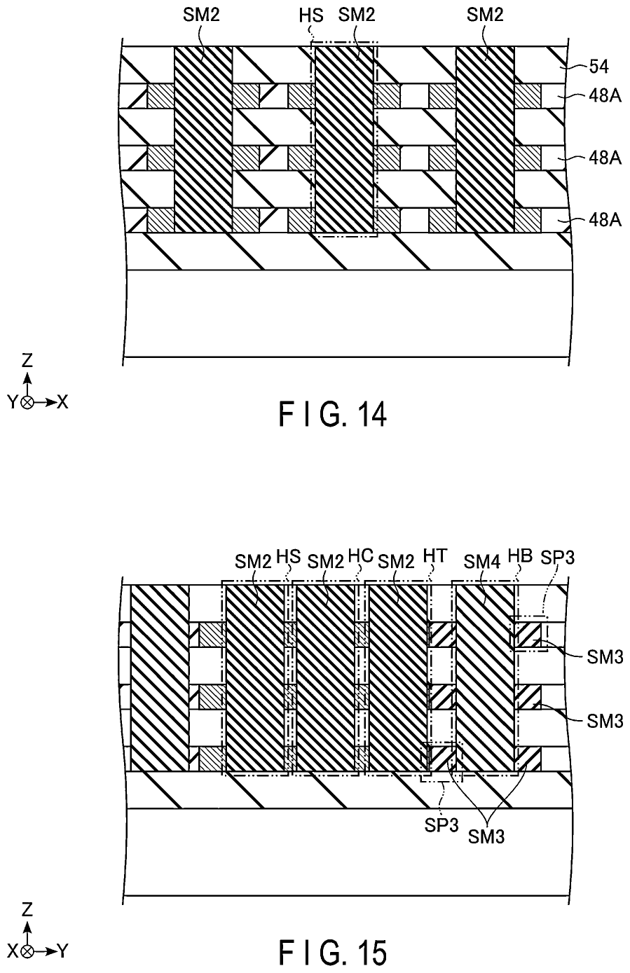

FIG. 13 illustrates a portion of the region illustrated in FIG. 3. FIG. 14 illustrates the region illustrated in FIG. 4. FIG. 15 illustrates the region illustrated in FIG. 7.

As illustrated in FIGS. 13 to 15, a sacrificial material SM2 is deposited in the holes HS, HC, and HT. In one example, the sacrificial material SM2 includes silicon oxide and/or polysilicon. Examples of deposition methods include CVD. By the deposition, the holes HS, HC, and HT are filled with the sacrificial material SM2.

The sacrificial material SM1 in the hole HB is removed. Examples of removal methods include CVD. By the removal, the hole HB is formed again.

Portions of the insulator 48A exposed in the hole HB are removed. Examples of removal methods include wet etching. By the removal, a space SP3 is formed around the hole HB in the layer where the insulator 48A is located. The space SP3 has an annular shape surrounding the hole HB. The removal is performed until the space SP3 reaches the semiconductor 42A. By the removal, the semiconductor 42A is exposed in the space SP3.

Portions of the semiconductor 42A exposed in the space SP3 are removed. Examples of removal methods include wet etching. Chemical solution of the wet etching reaches the semiconductor 42A from the space SP3. By the wet etching, the upper portion of the semiconductor 42A is removed in the layer where the insulator 48A is located. By the removal, surfaces of the semiconductor 42A exposed in the space SP3 move back. By the removal, the semiconductor 42A becomes the semiconductor 42B. By the removal, the space SP3 extends in the layer where the insulator 48A is located.

A sacrificial material SM3 is deposited in the space SP3. In one example, the sacrificial material SM3 contains silicon nitride. Examples of deposition methods include CVD. By the deposition, the space SP3 is filled with the sacrificial material SM3.

The sacrificial material SM3 formed in the hole HB is removed in the process of forming the sacrificial material SM3. Thus, the hole HB is formed again.

A sacrificial material SM4 is deposited in the hole HB. In one example, the sacrificial material SM4 includes silicon oxide and/or polysilicon. Examples of deposition methods include CVD. By the deposition, the hole HB is filled with the sacrificial material SM4.

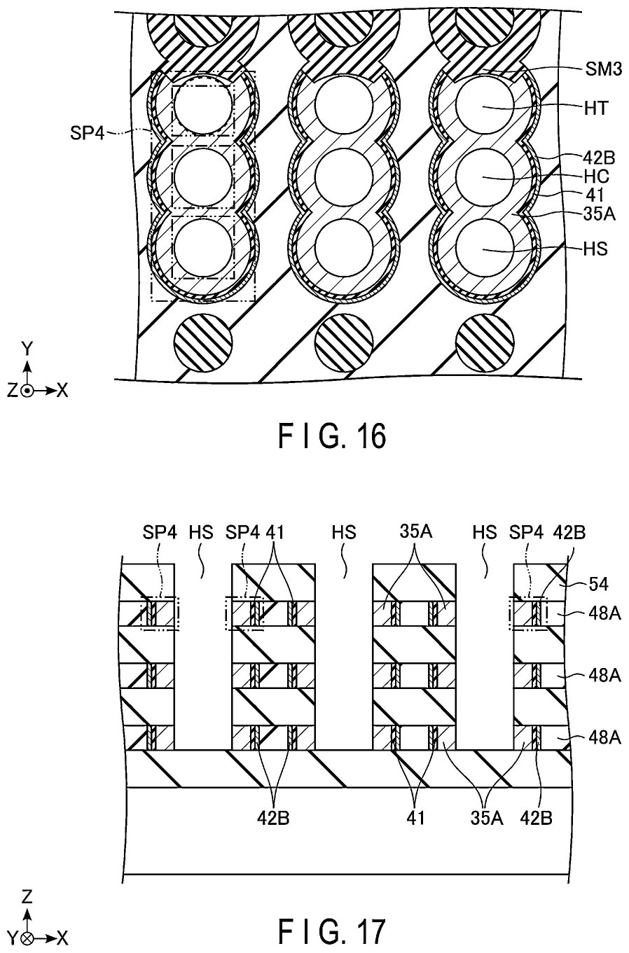

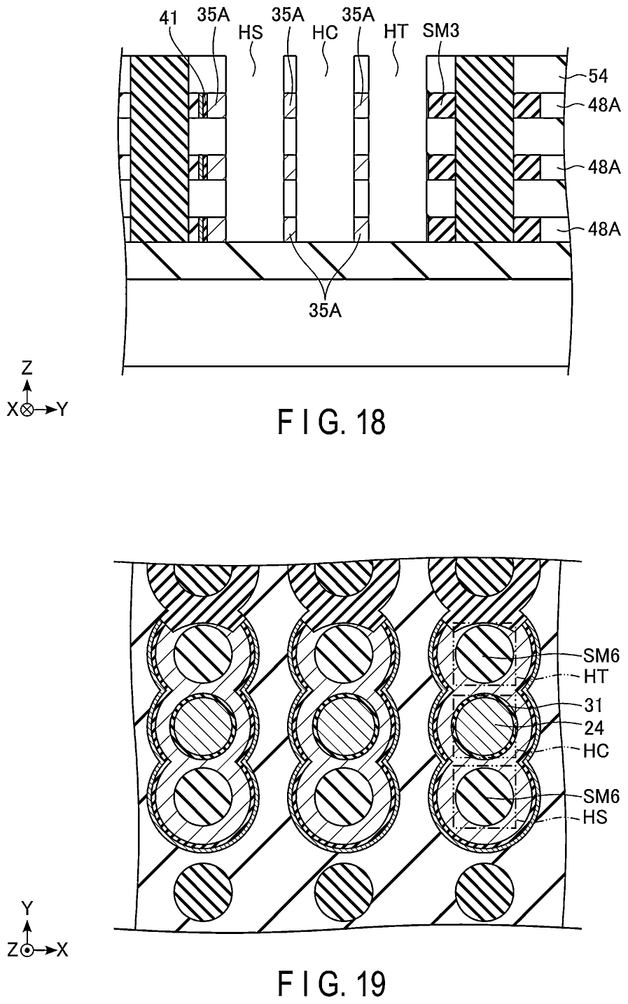

FIG. 16 illustrates a portion of the region illustrated in FIG. 3. FIG. 17 illustrates the region illustrated in FIG. 4. FIG. 18 illustrates the region illustrated in FIG. 7.

As illustrated in FIGS. 16 to 18, the sacrificial material SM2 is removed. Examples of removal methods include a set of a lithographic process and RIE. By the removal, the holes HS, HC, and HT are formed again. The semiconductor 42B is exposed in the holes HS, HC, and HT by the formation of the holes HS, HC, and HT.

Portions of the semiconductor 42B exposed in the holes HS, HC, and HT are removed. Examples of removal methods include wet etching. The removal is performed until the semiconductor 42B reaches the thickness of the semiconductor 42. By the removal, surfaces of the semiconductor 42B exposed in the holes HS, HC, and HT move back. By the removal, a space SP4 is formed in a region where the semiconductor 42B has been located in the layer where the insulator 48A is located. The space SP4 exposes the sacrificial material SM3 in a region on the upper side of the hole HT in the semiconductor 42B in the layer where the insulator 48A is located.

The insulator 41 is formed on surfaces of the semiconductor 42B exposed in the space SP4. Examples of the formation include oxidation of the surface of the semiconductor 42B. The insulator 41 is not formed on a surface of the sacrificial material SM3 exposed in the space SP4 in the region on the upper side of the hole HT. This is because the sacrificial material SM3 contains a material different from the material of the semiconductor 42B.

A semiconductor 35A is deposited on a portion of the insulator 41 exposed in the space SP4. The semiconductor 35A is a component to be shaped into the semiconductor 35 by a later step. Examples of deposition methods include CVD.

The semiconductor 35A formed in the holes HS, HC, and HT is removed in the process of depositing the semiconductor 35A. Thus, the holes HS, HC, and HT are formed again.

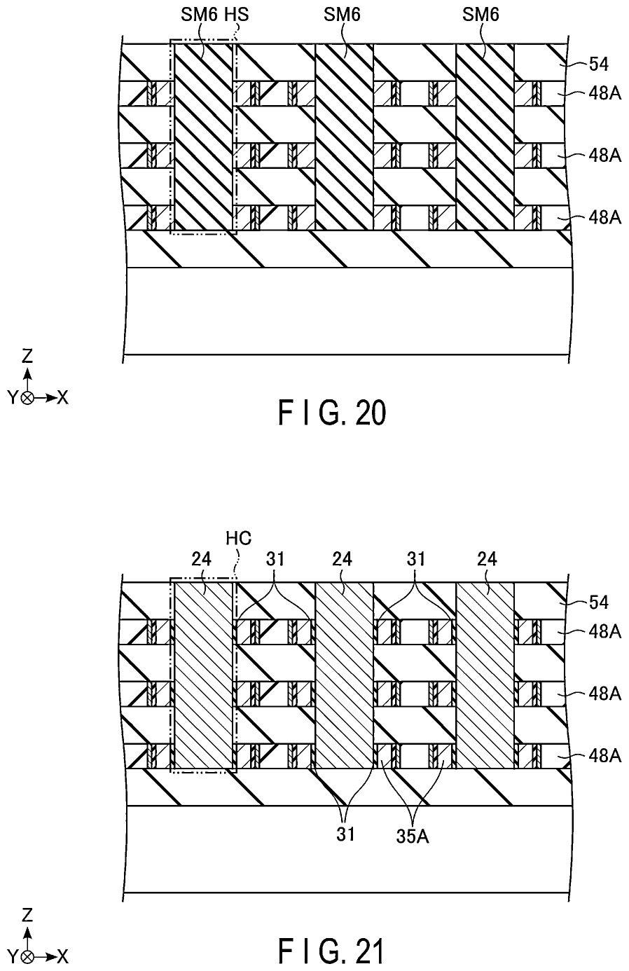

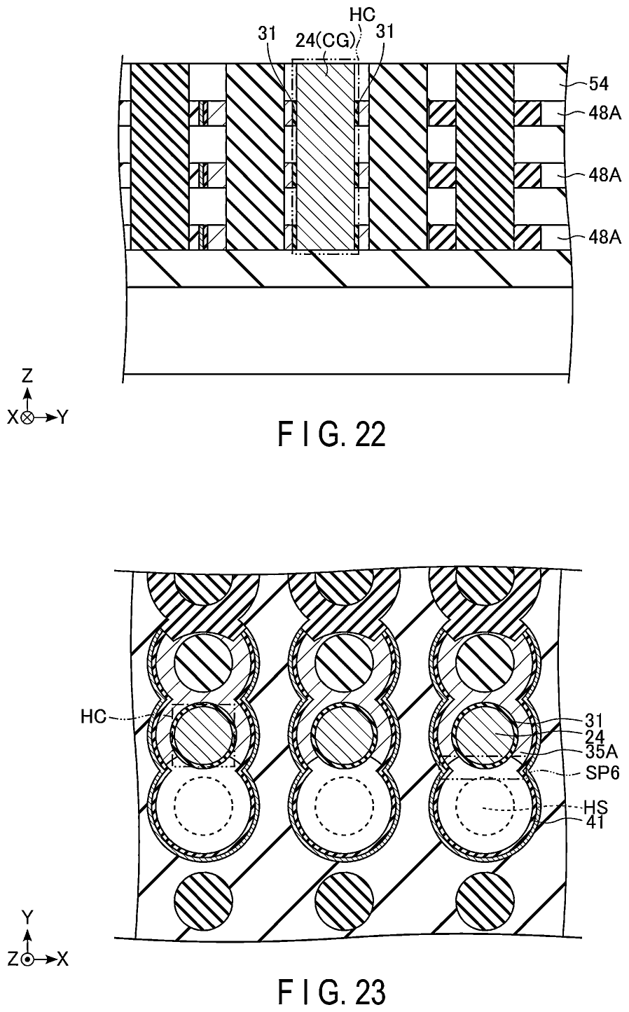

FIG. 19 illustrates a portion of the region illustrated in FIG. 3. FIG. 20 illustrates the region illustrated in FIG. 4. FIG. 21 illustrates the region illustrated in FIG. 5. FIG. 22 illustrates the region illustrated in FIG. 7.

As illustrated in FIGS. 19, 20, 21, and 22, a sacrificial material SM6 is deposited in the holes HS and HT. In one example, the sacrificial material SM6 includes silicon oxide and/or polysilicon. Examples of deposition methods include CVD. By the deposition, the holes HS and HT are filled with the sacrificial material SM6.

The holes HC are not filled. In an example of a method therefor, after the holes HS, HC, and HT are filled with the sacrificial material SM6, the sacrificial material SM6 in the hole HC is removed.

The insulator 31 is formed on a portion of the semiconductor 35A exposed in the hole HC. Examples of forming methods include oxidation of the semiconductor 35A.

The semiconductor 24 is deposited in the hole HC. Examples of deposition methods include CVD. By the deposition, the hole HC is filled with the semiconductor 24.

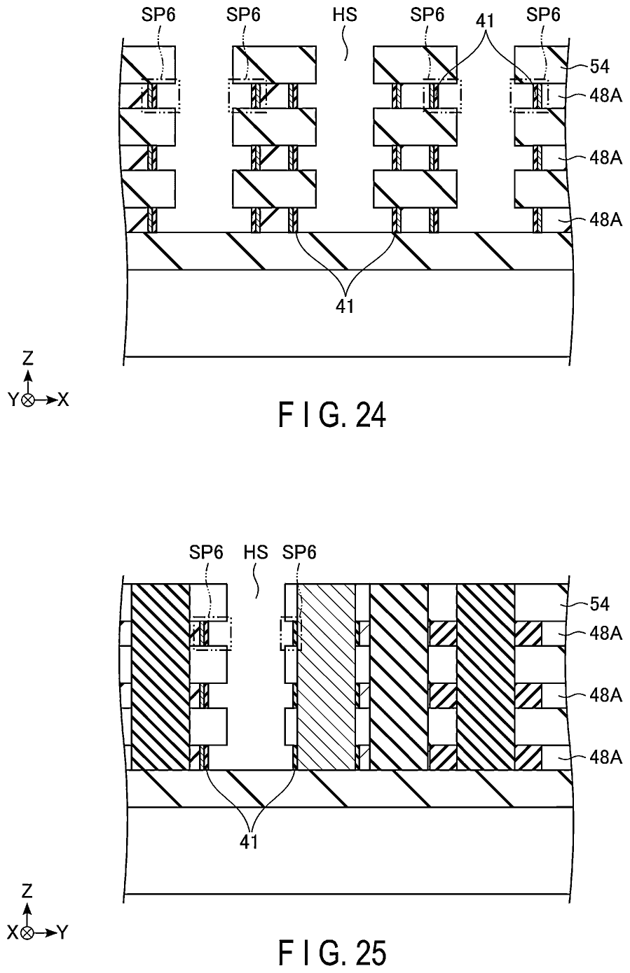

FIG. 23 illustrates a portion of the region illustrated in FIG. 3. FIG. 24 illustrates the region illustrated in FIG. 4. FIG. 25 illustrates the region illustrated in FIG. 7.

As illustrated in FIGS. 23 to 25, the sacrificial material SM6 in the hole HS is removed. Examples of removal methods include RIE. By the removal, the hole HS is formed again. Due to the formation of the hole HS, the semiconductor 35A is exposed in the hole HS in the layer where the insulator 48A is located.

Portions of the semiconductor 35A exposed in the hole HS are removed. Examples of removal methods include wet etching. By the removal, a space SP6 is formed around the hole HS in the layer where the insulator 48A is located. The space SP6 has an annular shape surrounding the hole HS. By the removal, the insulator 41 is exposed in the space SP6.

By partial removal of the semiconductor 35A, the space SP6 extends to a region of the semiconductor 35A on the upper side of the hole HS. In the space SP6, a lower portion of the portion of the semiconductor 35A on the sides of the semiconductor 24 (that is, the right side and the left side) is removed. Thus, the semiconductor 35A is exposed on the sides of the semiconductor 24.

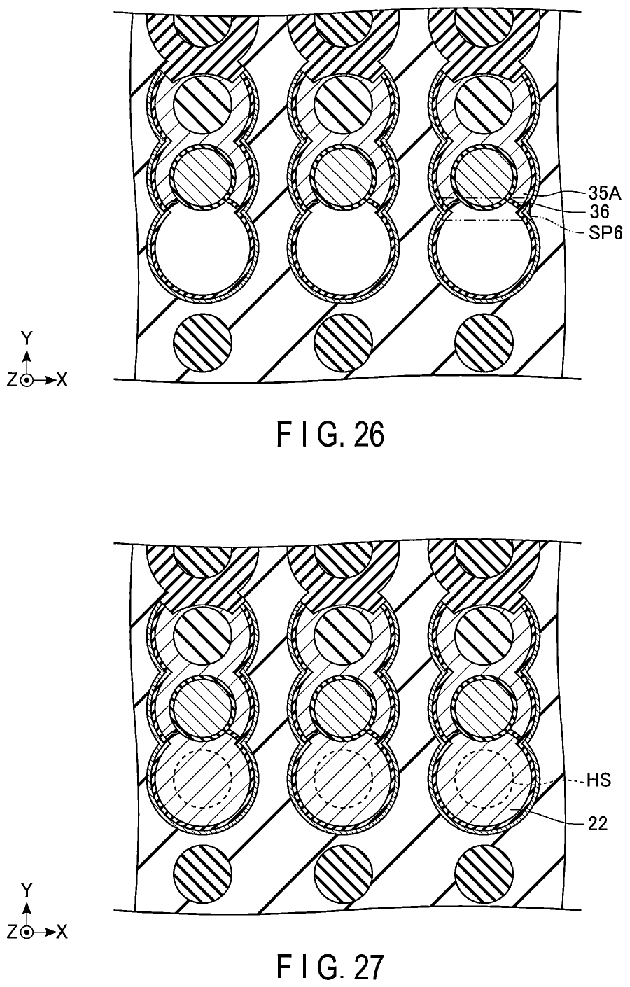

FIG. 26 illustrates a portion of the region illustrated in FIG. 3. As illustrated in FIG. 26, the insulator 36 is formed on portions of the semiconductor 35A exposed by the space SP6. Examples of forming methods include oxidation of the semiconductor 35A.

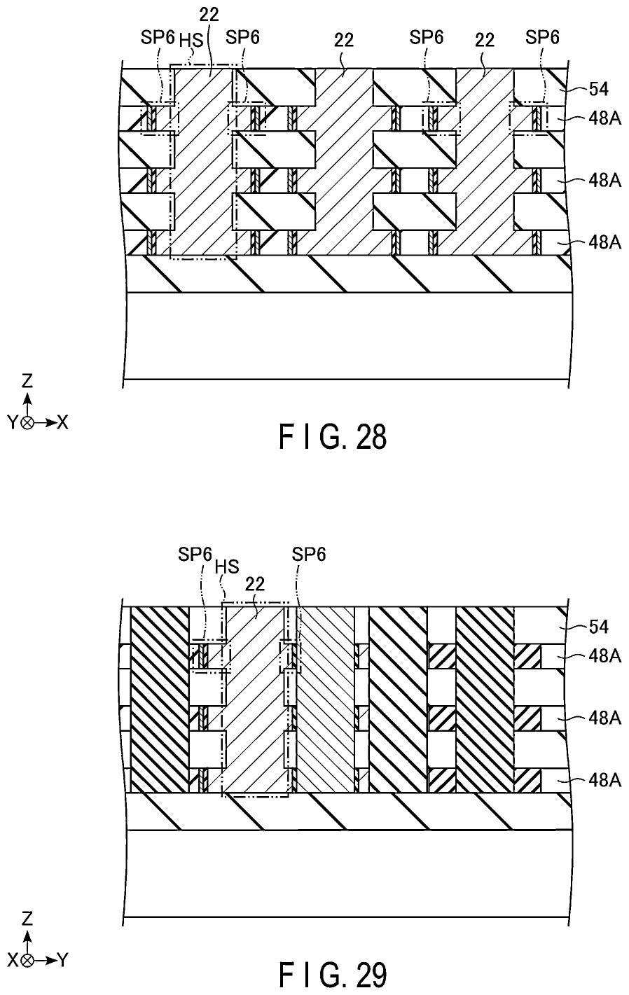

FIG. 27 illustrates a portion of the region illustrated in FIG. 3. FIG. 28 illustrates the region illustrated in FIG. 4. FIG. 29 illustrates the region illustrated in FIG. 7.

As illustrated in FIGS. 27 to 29, the semiconductor 22 is deposited in the hole HS and the space SP6. Examples of deposition methods include CVD. By the deposition, the hole HS and the space SP6 is filled with the semiconductor 22.

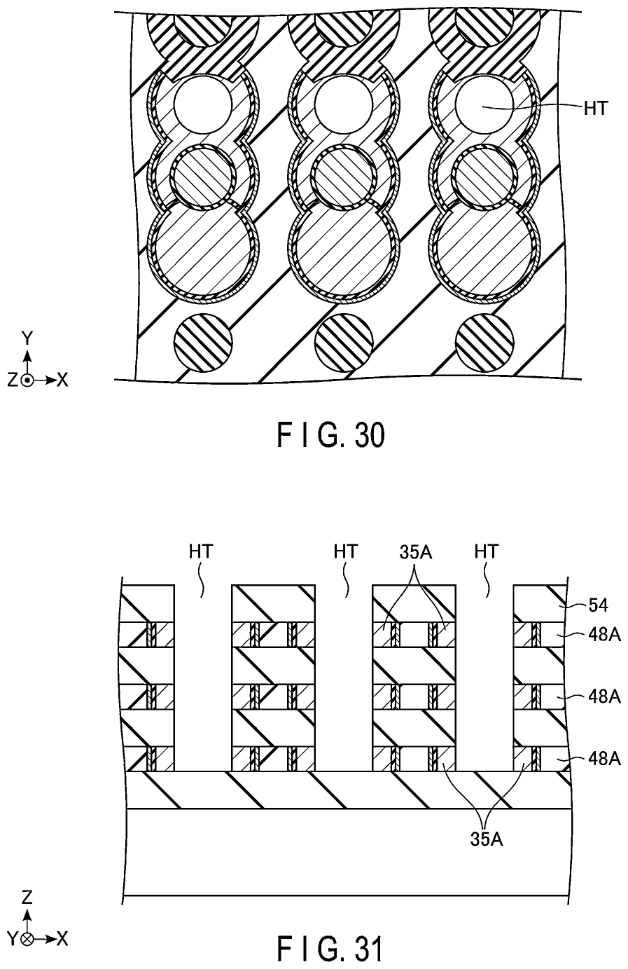

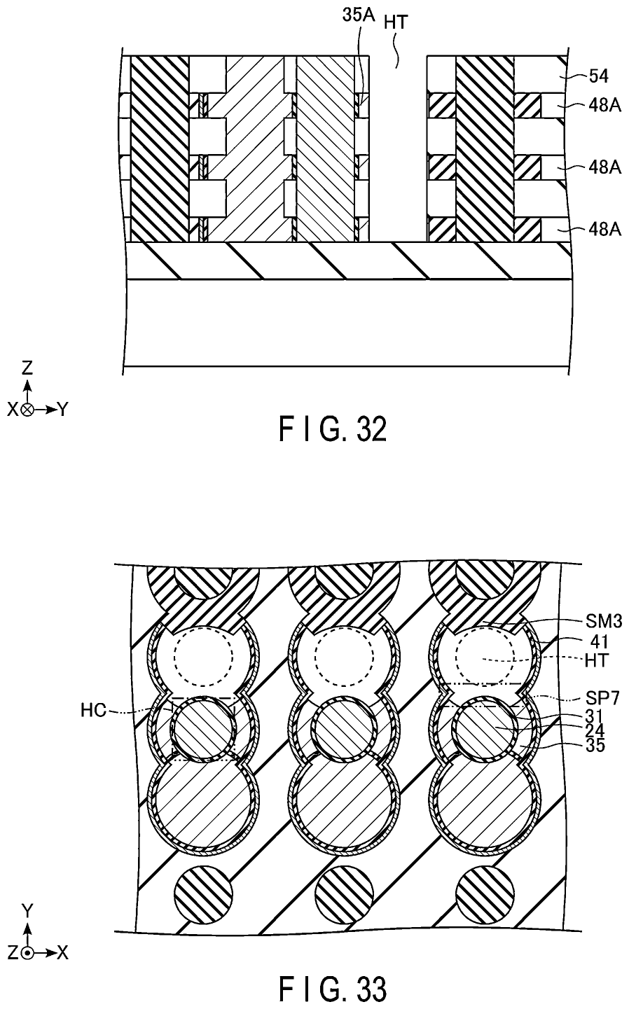

FIG. 30 illustrates a portion of the region illustrated in FIG. 3. FIG. 31 illustrates the region illustrated in FIG. 6. FIG. 32 illustrates the region illustrated in FIG. 7.

As illustrated in FIGS. 30 to 32, the sacrificial material SM6 in the hole HT is removed. Examples of removal methods include RIE. By the removal, the hole HT is formed again. Due to the formation of the hole HT, the semiconductor 35A is exposed in the hole HT in the layer where the insulator 48A is located.

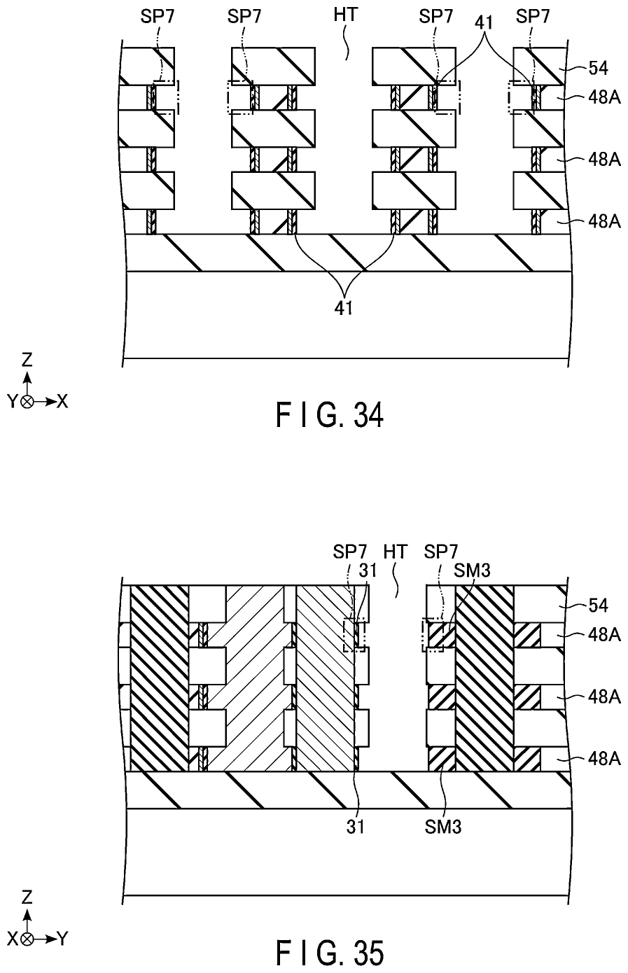

FIG. 33 illustrates a portion of the region illustrated in FIG. 3. FIG. 34 illustrates the region illustrated in FIG. 6. FIG. 35 illustrates the region illustrated in FIG. 7.

As illustrated in FIGS. 33 to 35, portions of the semiconductor 35A exposed in the hole HT are removed. Examples of removal methods include wet etching. By the removal, a space SP7 is formed around the hole HT in the layer where the insulator 48A is located. The space SP7 has an annular shape surrounding the hole HT. By the removal, the insulator 41, the sacrificial material SM3, and the insulator 31 are exposed in the space SP7.

By partial removal of the semiconductor 35A, in the space SP7, an upper portion of a portion of the semiconductor 35A on the sides of the semiconductor 24 (that is, the right side and the left side) are removed. Thus, the semiconductor 35A becomes the semiconductor 35.

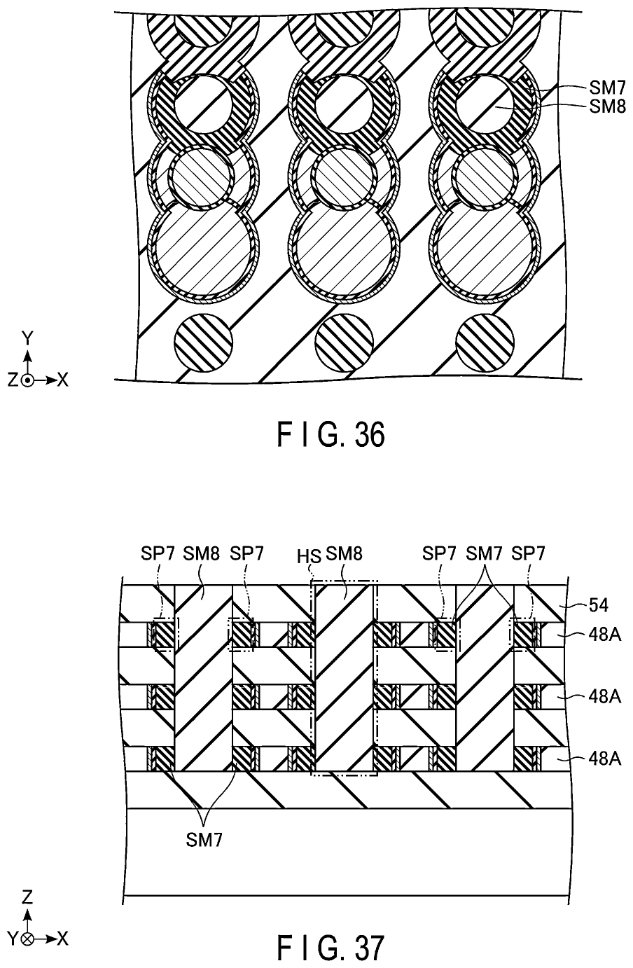

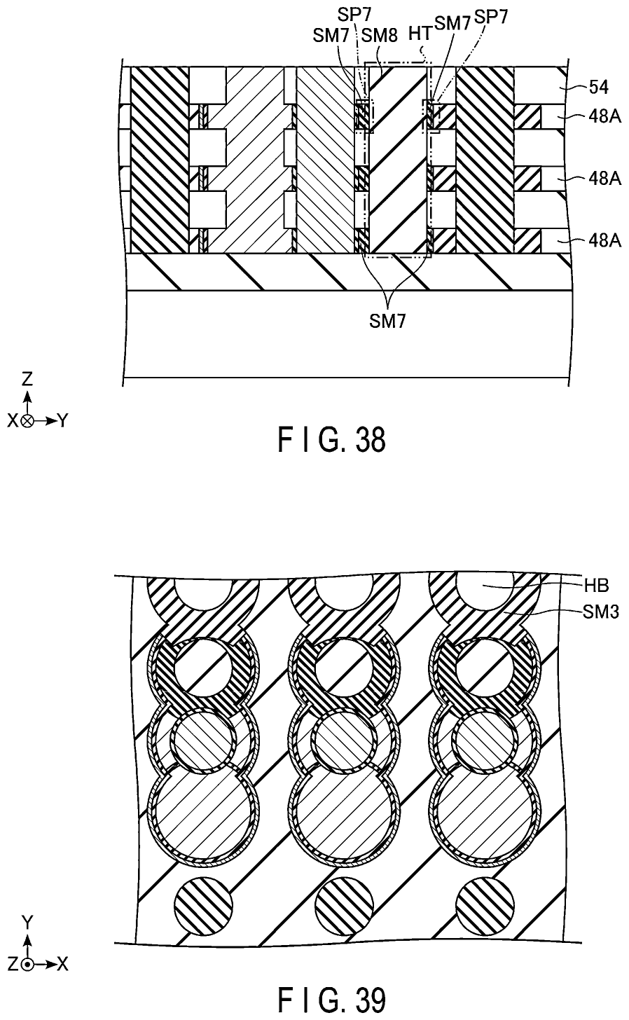

FIG. 36 illustrates a portion of the region illustrated in FIG. 3. FIG. 37 illustrates the region illustrated in FIG. 6. FIG. 38 illustrates the region illustrated in FIG. 7.

As illustrated in FIGS. 36 to 38, a sacrificial material SM7 is deposited in the space SP7. In one example, the sacrificial material SM7 is silicon nitride. Examples of deposition methods include CVD. By the deposition, the space SP7 is filled with the sacrificial material SM7.

A sacrificial material SM8 is deposited in the hole HT. In one example, the sacrificial material SM8 includes silicon oxide and/or polysilicon. Examples of deposition methods include CVD. By the deposition, the holes HT are filled with the sacrificial material SM8.

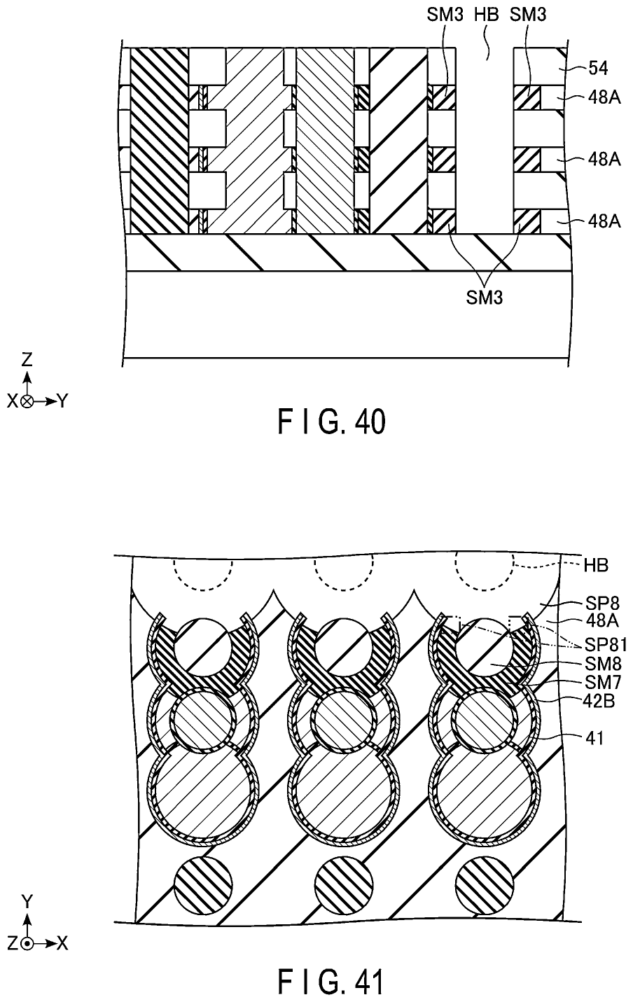

FIG. 39 illustrates a portion of the region illustrated in FIG. 3. FIG. 40 illustrates the region illustrated in FIG. 7.

As illustrated in FIGS. 39 and 40, the sacrificial material SM4 in the hole HB is removed. Examples of removal methods include RIE. By the removal, the hole HB is formed again. Due to the formation of the hole HB, the sacrificial material SM3 is exposed in the hole HB in the layer where the insulator 48A is located.

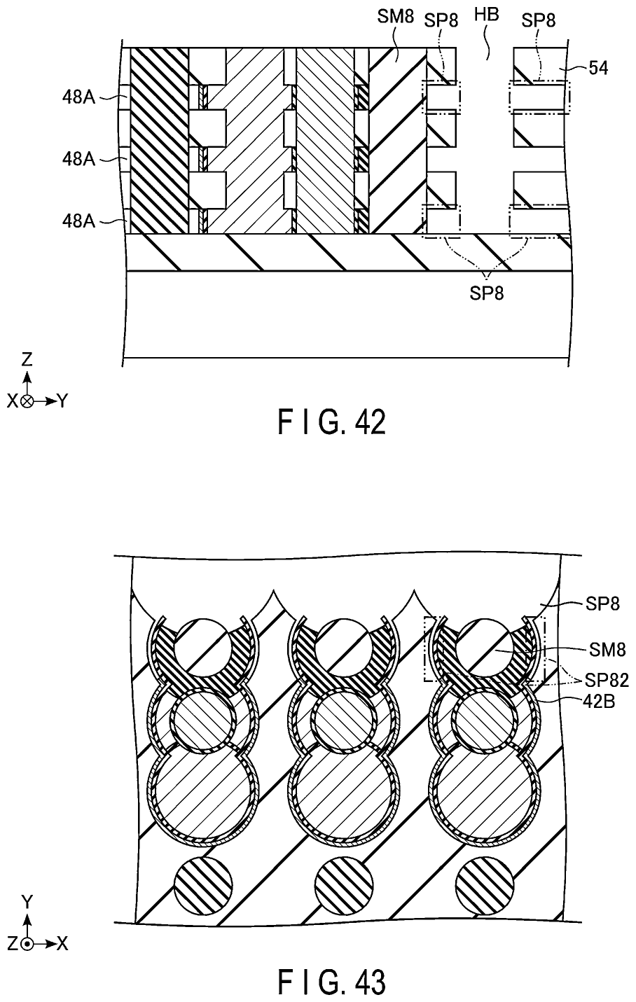

FIG. 41 illustrates a portion of the region illustrated in FIG. 3. FIG. 42 illustrates the region illustrated in FIG. 7.

As illustrated in FIGS. 41 and 42, the sacrificial material SM3 is removed. Examples of removal methods include wet etching. By the removal, a space SP8 is formed in a region where the sacrificial material SM3 has been located in the layer where the insulator 48A is located. In the space SP8, portions of the insulator 48A are exposed.

The portions of the insulator 48A exposed in the space SP8 is removed. Examples of removal methods include wet etching. By the removal, the space SP8 extends in the layer where the insulator 48A is located. The partial removal of the insulator 48A is continued until the portion between the holes HB arranged in the X direction in the insulator 48A is removed. As a result, the space SP8 has a shape in which annular shapes surrounding the hole HB are combined. In the space SP8, the sacrificial material SM8, the insulator 41, and the semiconductor 42B are exposed.

The partial removal of the insulator 48A also removes an upper portion of a portion of the sacrificial material SM7 on sides (that is, a right side and a left side) of the sacrificial material SM8. As a result, the space SP8 includes portions SP81 in an upper portion of the portion of the sacrificial material SM7 on the sides of the sacrificial material SM8.

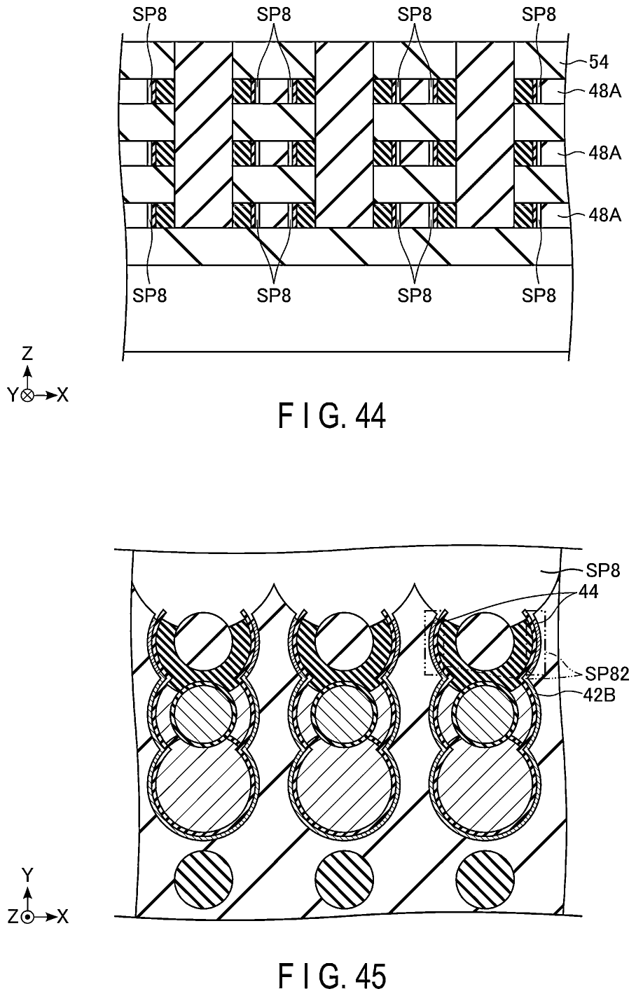

FIG. 43 illustrates a portion of the region illustrated in FIG. 3. FIG. 44 illustrates the region illustrated in FIG. 6.

As illustrated in FIGS. 43 and 44, portions of the semiconductor 42B exposed in the space SP8 are removed. Examples of removal methods include wet etching. By the removal, the space SP8 extends over regions where the semiconductor 42B has been located and include portions SP82. Lower ends of the portions SP82 reach the vicinity of a lower end of the sacrificial material SM8. The insulator 41 also remains by partial removal of the semiconductor 42B.

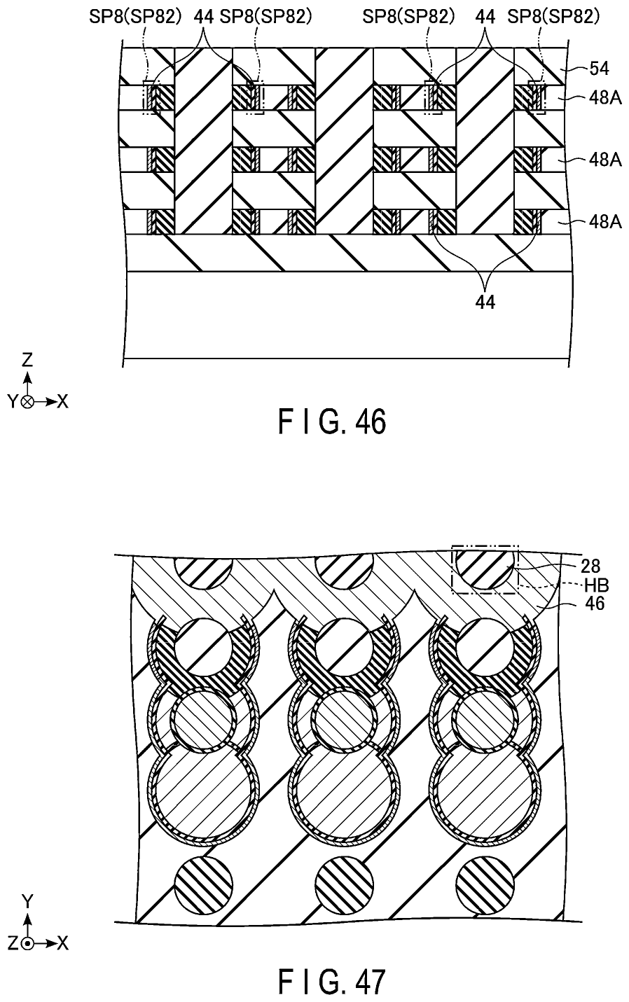

FIG. 45 illustrates a portion of the region illustrated in FIG. 3. FIG. 46 illustrates the region illustrated in FIG. 6.

As illustrated in FIGS. 45 and 46, the semiconductor 44 is deposited in the portions SP82 of the space SP8. Examples of deposition methods include CVD. By the deposition, the space SP8 is filled with the semiconductor 44.

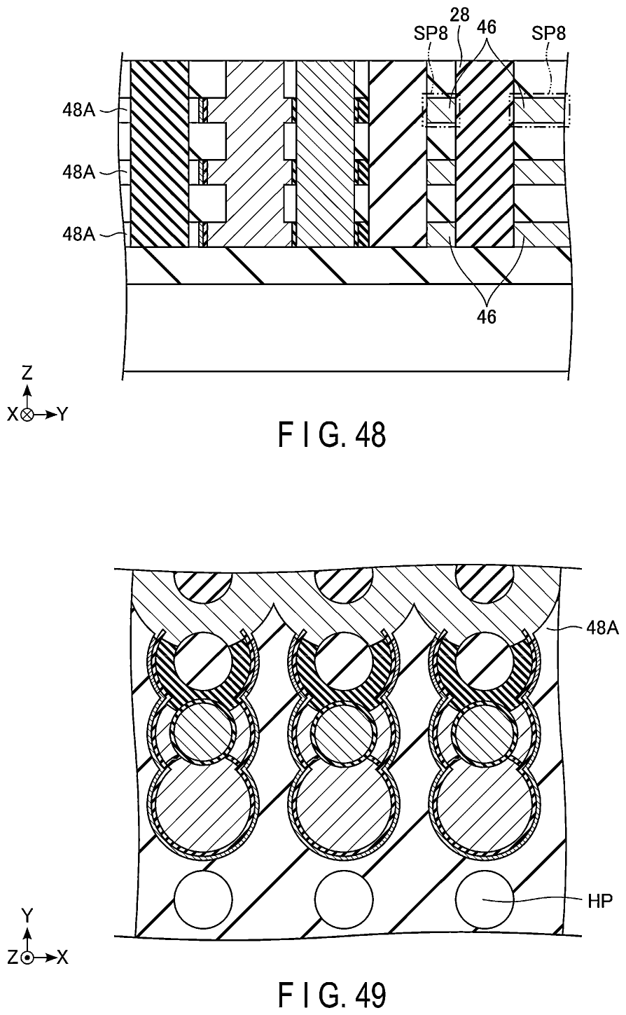

FIG. 47 illustrates a portion of the region illustrated in FIG. 3. FIG. 48 illustrates the region illustrated in FIG. 7.

As illustrated in FIGS. 47 and 48, the conductor 46 is deposited on the entire space SP8 except for the portions SP82. Examples of deposition methods include CVD. By the deposition, the entire space SP8 except the portions SP82 is filled with the conductor 46.

The conductor 46 deposited in the hole HB is removed in the process of depositing the conductor 46. Thus, the hole HB is formed again.

An insulator 28 is deposited in the hole HB. Examples of deposition methods include CVD. By the deposition, the hole HB is filled with the insulator 28.

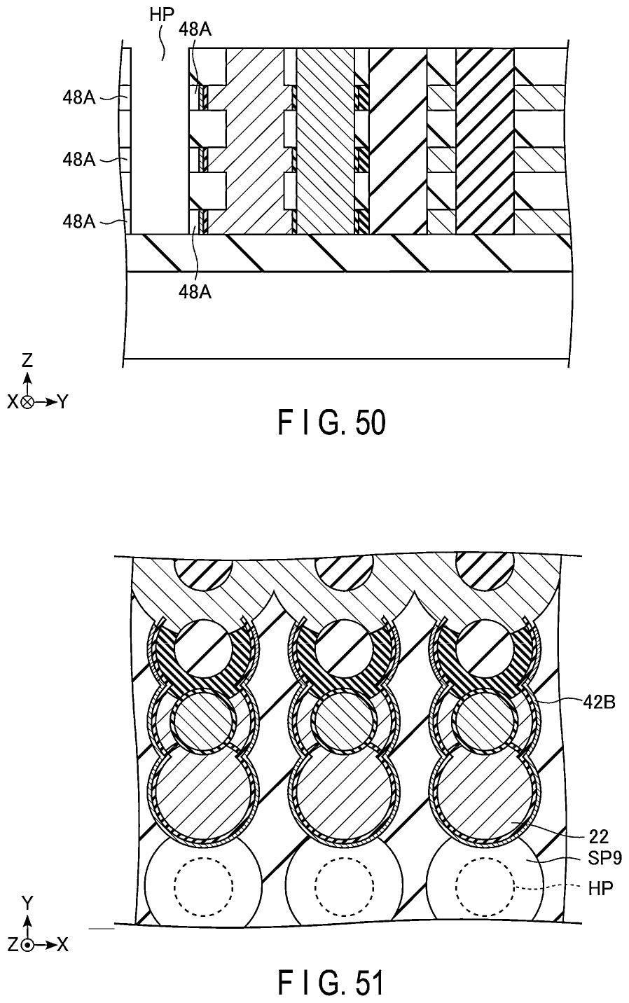

FIG. 49 illustrates a portion of the region illustrated in FIG. 3. FIG. 50 illustrates the region illustrated in FIG. 7.

As illustrated in FIGS. 49 and 50, the sacrificial material SM1 in the hole HP is removed. Examples of removal methods include RIE. By the removal, the hole HP is formed again. Due to the formation of the hole HP, the insulator 48A is exposed in the hole HP in the layer where the insulator 48A is located.

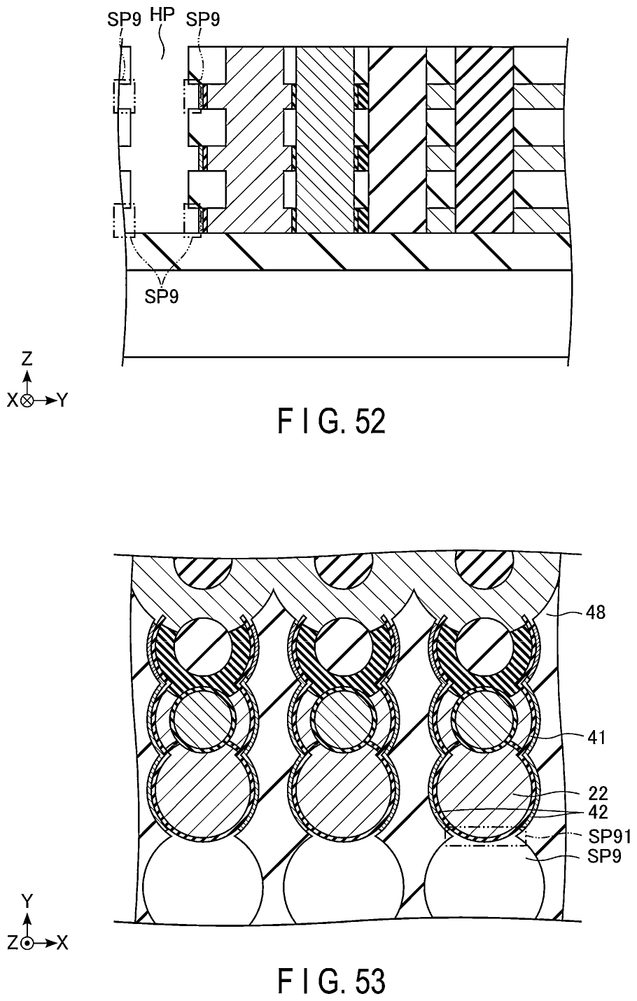

FIG. 51 illustrates a portion of the region illustrated in FIG. 3. FIG. 52 illustrates the region illustrated in FIG. 7.

As illustrated in FIGS. 51 and 52, a portion of the insulator 48A exposed in the hole HP is removed. Examples of removal methods include wet etching. By the removal, a space SP9 is formed around the hole HP in the layer where the insulator 48A is located. The space SP9 has an annular shape surrounding the hole HP. In the space SP9, portions of the semiconductor 42B along the lower end of the semiconductor 22 is exposed. By partial removal of the insulator 48A, the insulator 48A becomes the insulator 48.

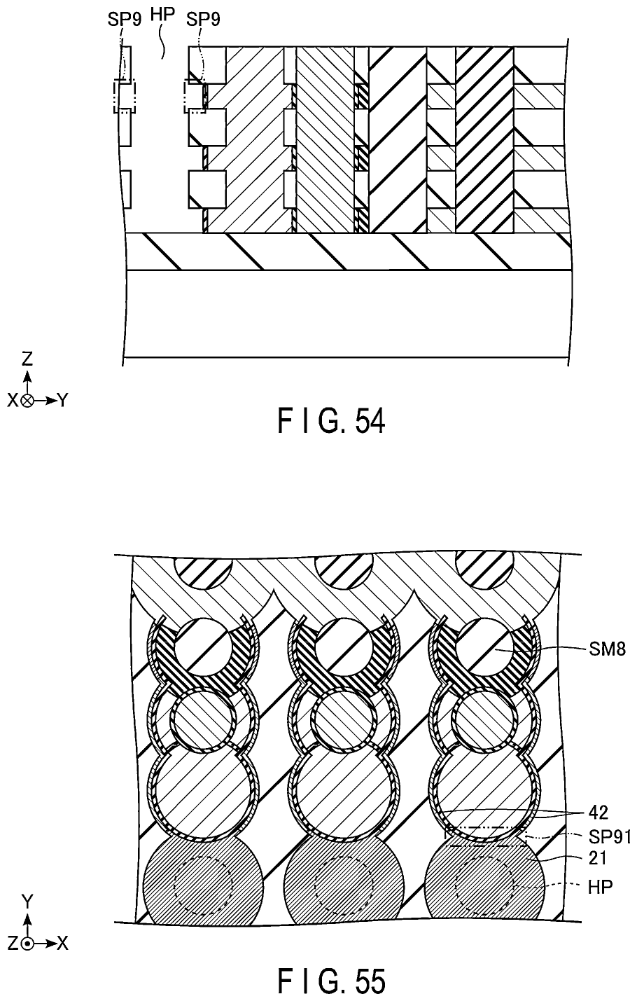

FIG. 53 illustrates a portion of the region illustrated in FIG. 3. FIG. 54 illustrates the region illustrated in FIG. 7.

As illustrated in FIGS. 53 and 54, a portion of the semiconductor 42B exposed in the space SP9 is removed. Examples of removal methods include wet etching. As a result of the removal, the space SP9 extends in a lower portion of the portion of the semiconductor 42B on the sides of the semiconductor 22 and include a portion SP91. The portion SP91 is located between the insulator 41 and the insulator 48. By partial removal of the semiconductor 42B, the semiconductor 42B becomes the semiconductor 42.

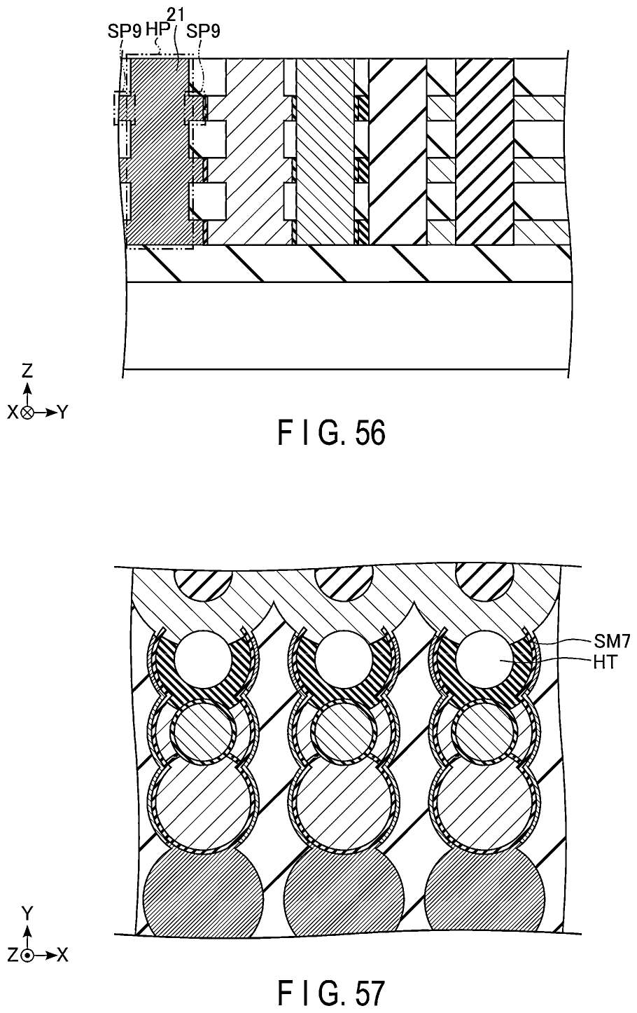

FIG. 55 illustrates a portion of the region illustrated in FIG. 3. FIG. 56 illustrates the region illustrated in FIG. 7.

As illustrated in FIGS. 55 and 56, the semiconductor 21 is deposited in the hole HP and the space SP9. Examples of deposition methods include CVD. By the deposition, the hole HP and the space SP9 are filled with the semiconductor 21. The semiconductor 21 is in contact with the semiconductor 42 in the portions SP91 of the space SP9.

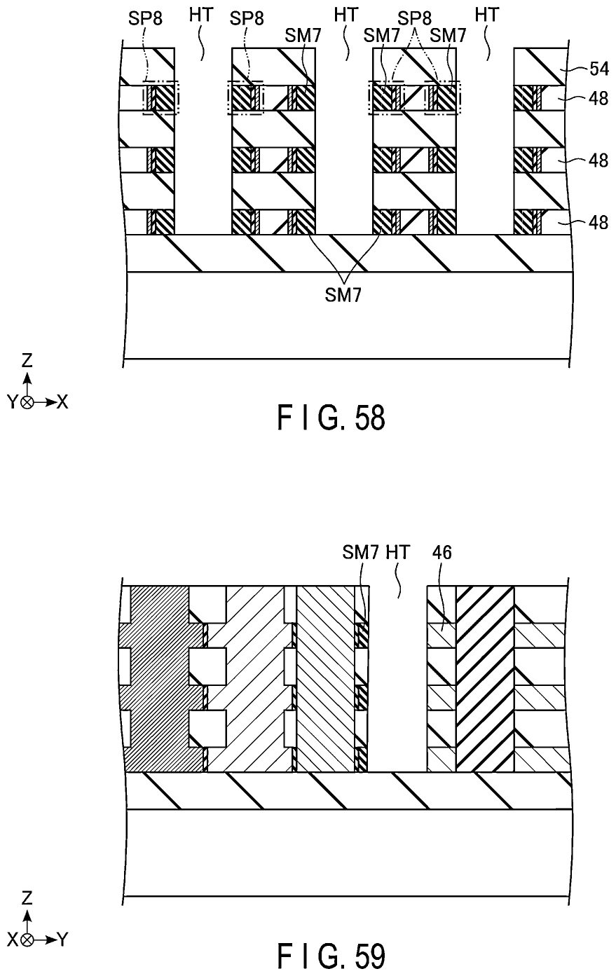

FIG. 57 illustrates a portion of the region illustrated in FIG. 3. FIG. 58 illustrates the region illustrated in FIG. 6. FIG. 59 illustrates the region illustrated in FIG. 7.

As illustrated in FIGS. 57 to 59, the sacrificial material SM8 in the hole HT is removed. Examples of removal methods include RIE. By the removal, the hole HT is formed again. The formation of the hole HT exposes the sacrificial material SM7 and the conductor 46 in the hole HT.

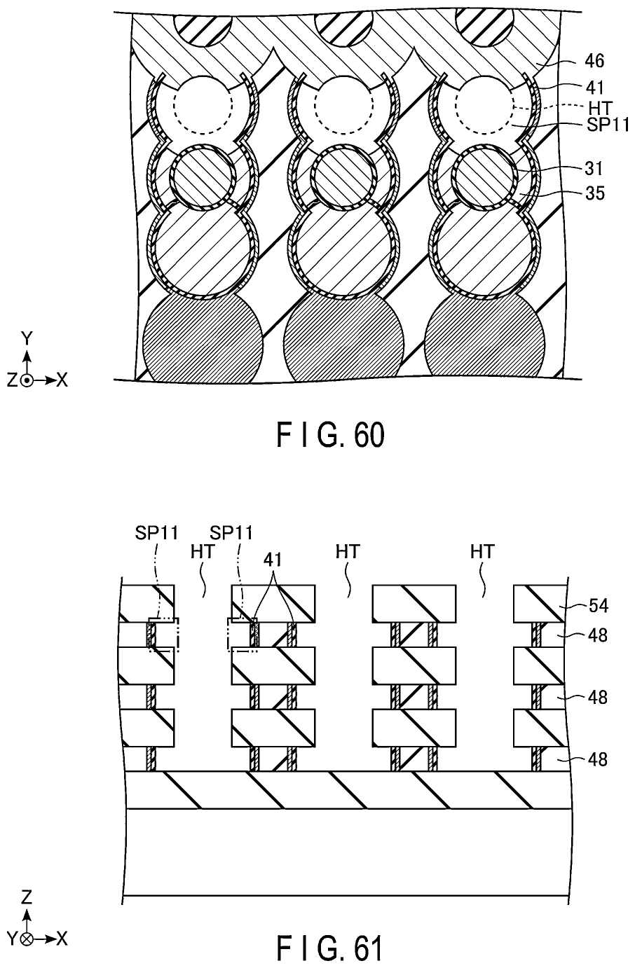

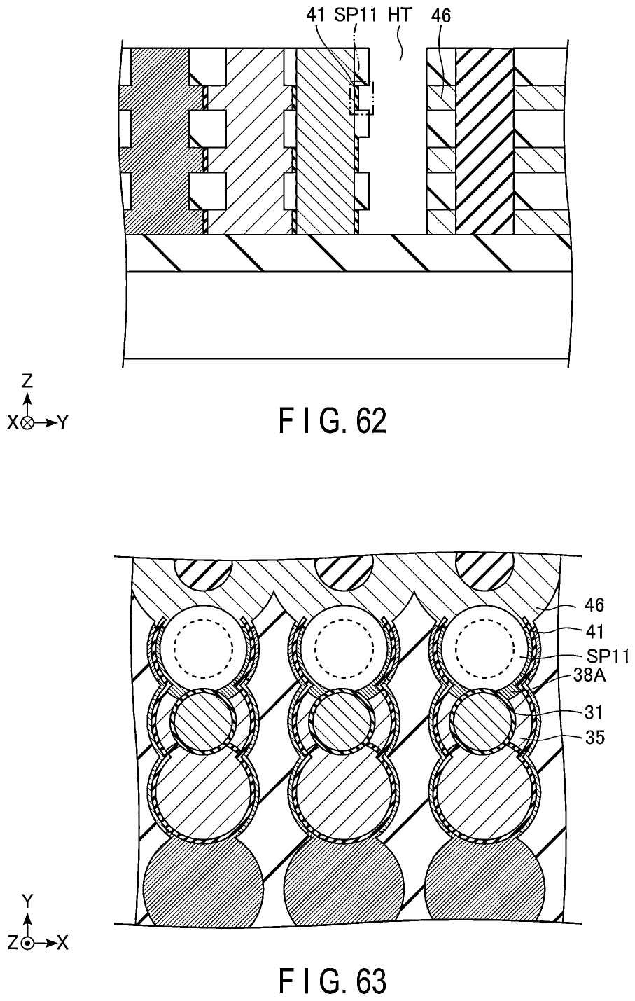

FIG. 60 illustrates a portion of the region illustrated in FIG. 3. FIG. 61 illustrates the region illustrated in FIG. 6. FIG. 62 illustrates the region illustrated in FIG. 7.

As illustrated in FIGS. 60 to 62, the sacrificial material SM7 is removed. Examples of removal methods include wet etching. By the removal, a space SP11 is formed in regions where the sacrificial material SM7 has been located in the layer where the insulator 48 is located. In the space SP11, the insulators 31 and 41, the conductor 46, and the semiconductor 35 are exposed.

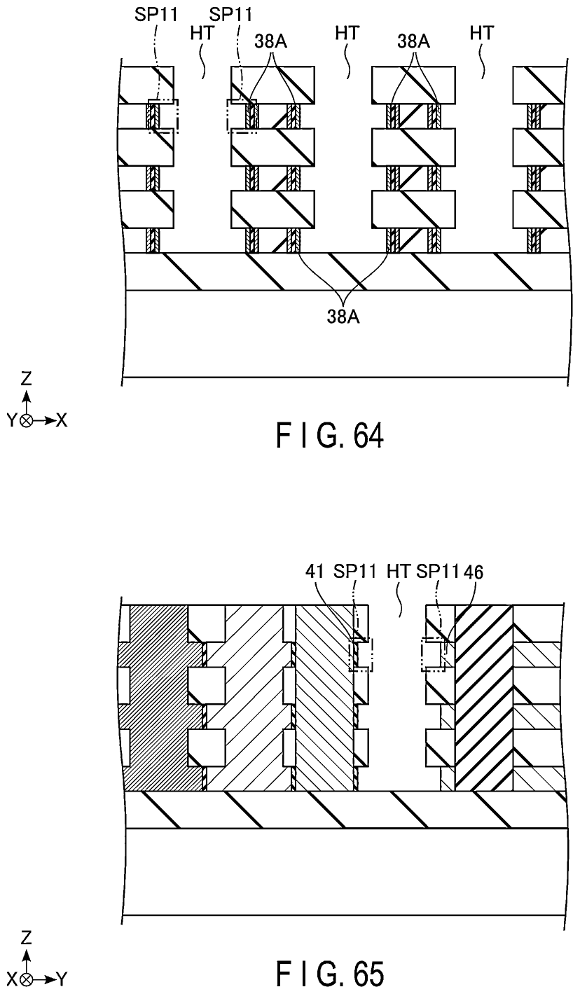

FIG. 63 illustrates a portion of the region illustrated in FIG. 3. FIG. 64 illustrates the region illustrated in FIG. 6. FIG. 65 illustrates the region illustrated in FIG. 7.

As illustrated in FIGS. 63 to 65, the conductor 38A is deposited in the space SP11. The conductor 38A is a component to be shaped into the conductor 38 in a later step. Examples of deposition methods include CVD. Portions of the conductor 38A exposed in the space SP11 are removed. By the removal, surfaces of the conductor 38A exposed in the space SP11 move back. As a result, the conductor 38A remains on the surface of the semiconductor 35 and the surface of the insulator 41 in the layer where the insulator 48 is located.

By partial removal of the conductor 38A, a portion of the conductor 46 exposed by the space SP11 in the layer where the insulator 48A is located are removed. By the removal, the space SP11 extends to regions where the portion of the conductor 46 has been located.

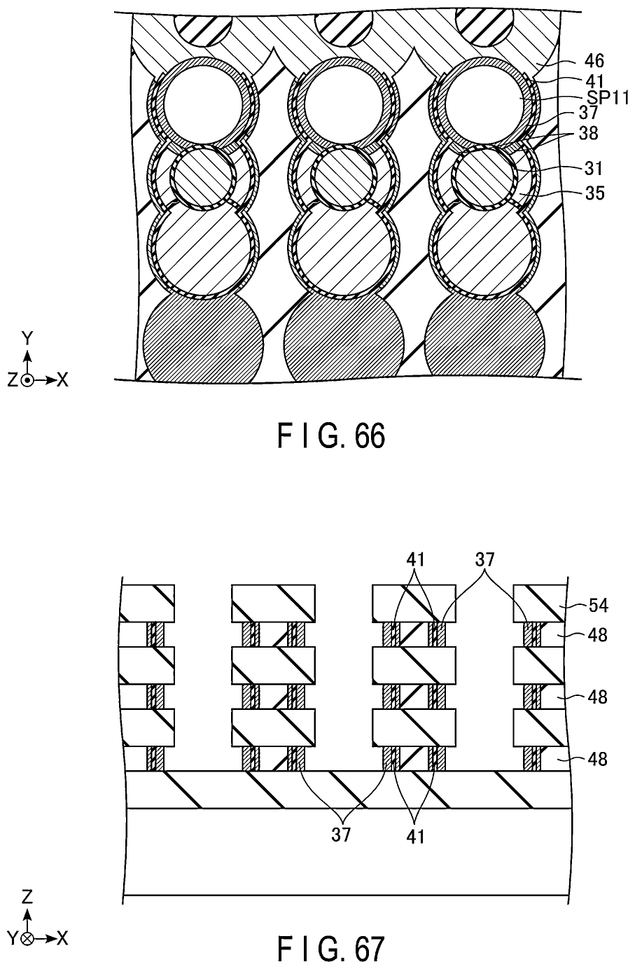

FIG. 66 illustrates a portion of the region illustrated in FIG. 3. FIG. 67 illustrates the region illustrated in FIG. 6. FIG. 68 illustrates the region illustrated in FIG. 7.

As illustrated in FIGS. 66 to 68, the semiconductor 37 is formed on the surface of the conductor 38A and the surface of the conductor 46. Examples of forming methods include oxidation of the surface of the conductor 38A and sputtering of a metal oxide. In one example, the semiconductor 37 is formed until the entire portion of the conductor 38A on the insulator 41 becomes the semiconductor 37. By the formation of the semiconductor 37, a part of the conductor 38A becomes the conductor 38.

As illustrated in FIGS. 3 to 7, the insulator 32 is deposited on the surface of the semiconductor 37. Examples of deposition methods include CVD.

The conductor 26 is deposited in the hole HB. Examples of deposition methods include CVD. By the deposition of the conductor 26, the hole HB is filled with the conductor 26. Thus, the structure illustrated in FIGS. 3 to 7 is completed.

### 1.3. Advantages (Advantageous Effects)

According to the first embodiment, the semiconductor 22 functioning as the gate of the transistor TrS and the semiconductor 24 are insulated by the insulator 31 surrounding the semiconductor 24 as the gate of the transistor TrC, and the semiconductor 24 and the conductor 26 functioning as the gate of the transistor TrT are insulated by the insulator 31 and the insulator 32 surrounding the conductor 26. In addition, the semiconductor 35 functioning as a floating gate of the transistor TrC is insulated from the semiconductor 22 by the insulator 36 and is in contact with the semiconductor 37 functioning as a channel of the transistor TrT. Then, the set of semiconductors 42 and 44 faces the semiconductors 22 and 35 and the semiconductor 37 via the insulator 41. With such a structure, the memory cell MC including the pair of transistors Trc and TrT constituting the gain cell structure and the transistor TrS coupled in series with the gain cell structure can be achieved.

In addition, the structure of the memory cell MC is formed by a combination of depositing and removing a semiconductor, an insulator, and a conductor using the holes HS, HC, and HT as the center. Such a forming method facilitates the formation of the plurality of memory cells MC in a plurality of layers arranged in the extending direction of the holes HS, HC, and HT. This is because deposition and removal of the semiconductor, the insulator, and the conductor in the plurality of layers can be performed in parallel.

### 1.4. Modifications

### 1.4.1. First Modification

Instead of the steps described above with reference to FIGS. 43 and 44, steps described below with reference to FIG. 69 may be performed. FIG. 69 illustrates a first modification of the structure of the manufacturing step of the memory device of the first embodiment. FIG. 69 illustrates a portion of the region illustrated in FIG. 3.

As illustrated in FIG. 69, the removal of the portions of the semiconductor 42B exposed in the space SP8 is continued longer than the removal in the steps described above with reference to FIGS. 43 and 44. As a result, the space SP8 reaches the region on the sides of the semiconductor 24.

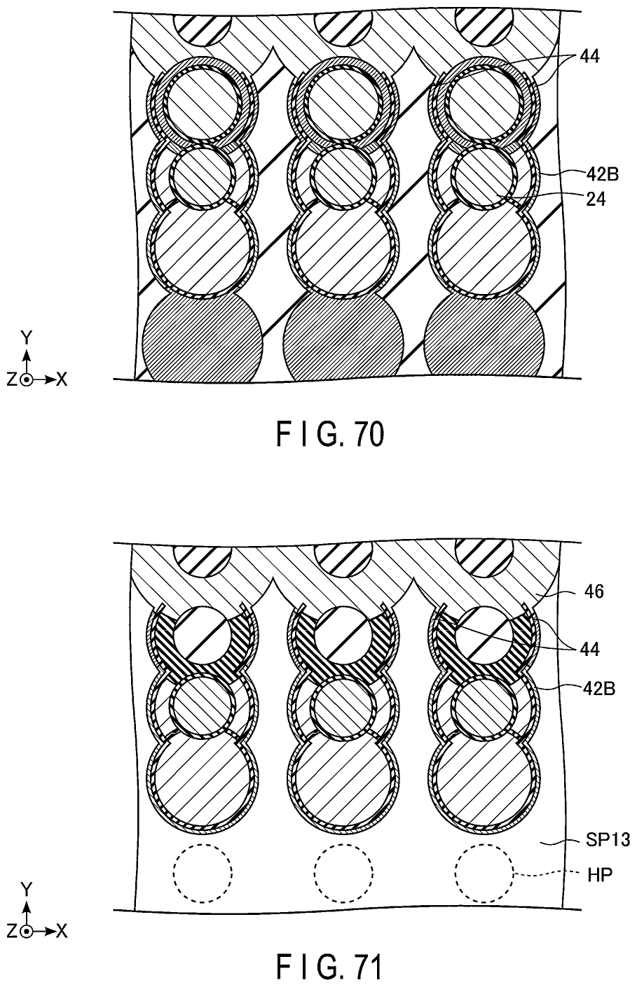

Based on the shapes of the portions SP82, as illustrated in FIG. 70, the semiconductor 44 formed by the steps described above with reference to FIGS. 45 and 46 reaches the sides of the semiconductor 24.

### 1.4.2. Second Modification

FIGS. 71 to 93 illustrate an example of a structure during manufacturing steps of a part of a memory device according to a second modification of the first embodiment.

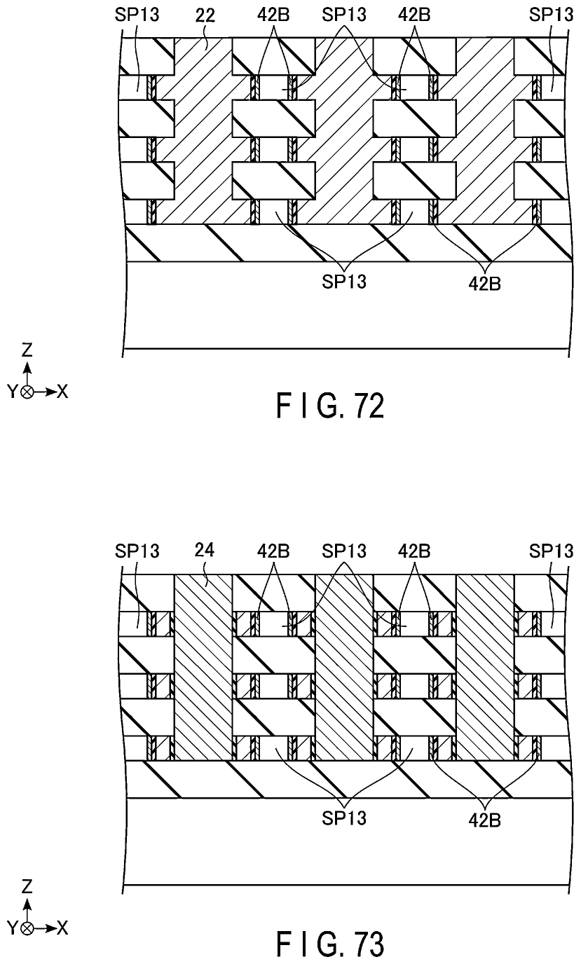

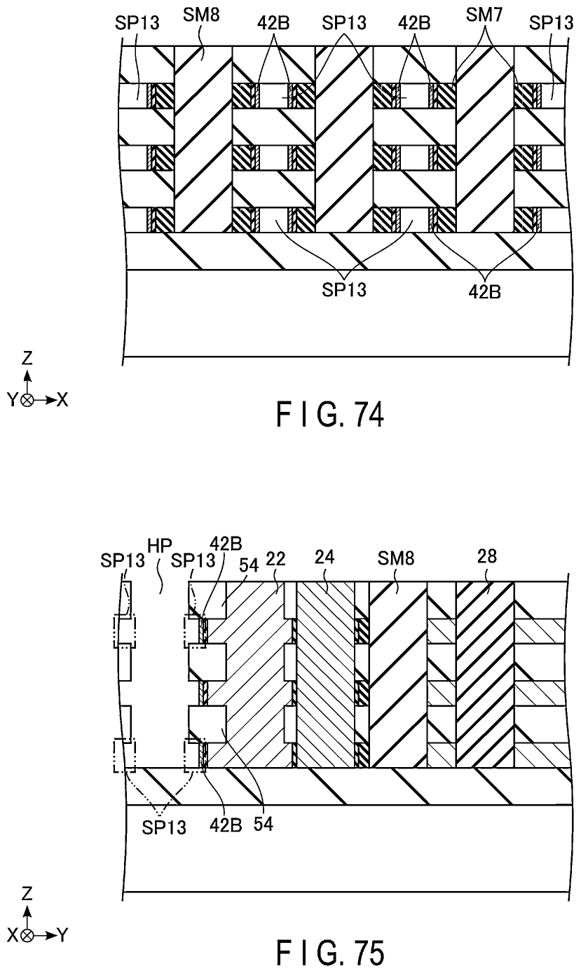

The steps described above with reference to FIGS. 49 and 50 continue to steps described below with reference to FIGS. 71 to 75. FIG. 71 illustrates a portion of the region illustrated in FIG. 3. FIG. 72 illustrates the region illustrated in FIG. 4. FIG. 73 illustrates the region illustrated in FIG. 5. FIG. 74 illustrates the region illustrated in FIG. 6. FIG. 75 illustrates the region illustrated in FIG. 7.

As illustrated in FIGS. 71 to 75, the insulator 48A is removed. Examples of removal methods include wet etching. By the removal, a space SP13 is formed in regions where the insulator 48A has been located in the layer where the insulator 48A has been located (that is, the layer in which the memory cell MC is located). In the space SP13, the semiconductors 42B and 44 and the conductor 46 are exposed.

The hole HP is formed again by removing the insulator 48A. The insulator 54 is exposed in the hole HP and the space SP13.

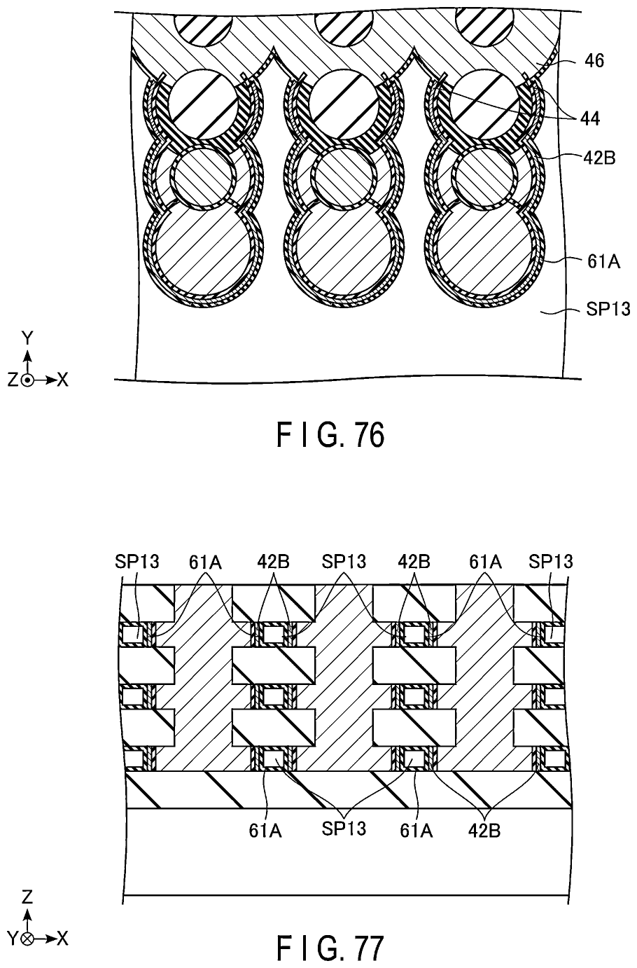

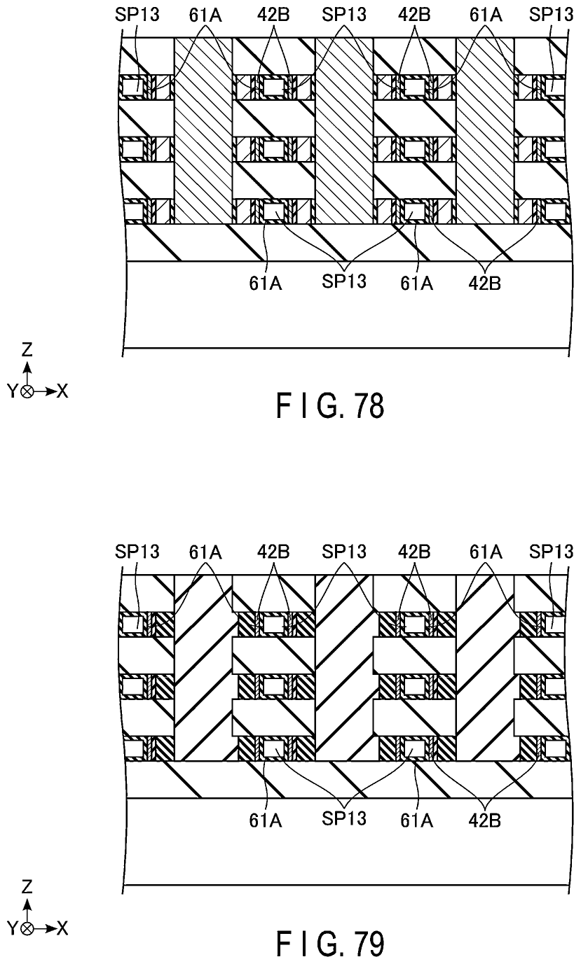

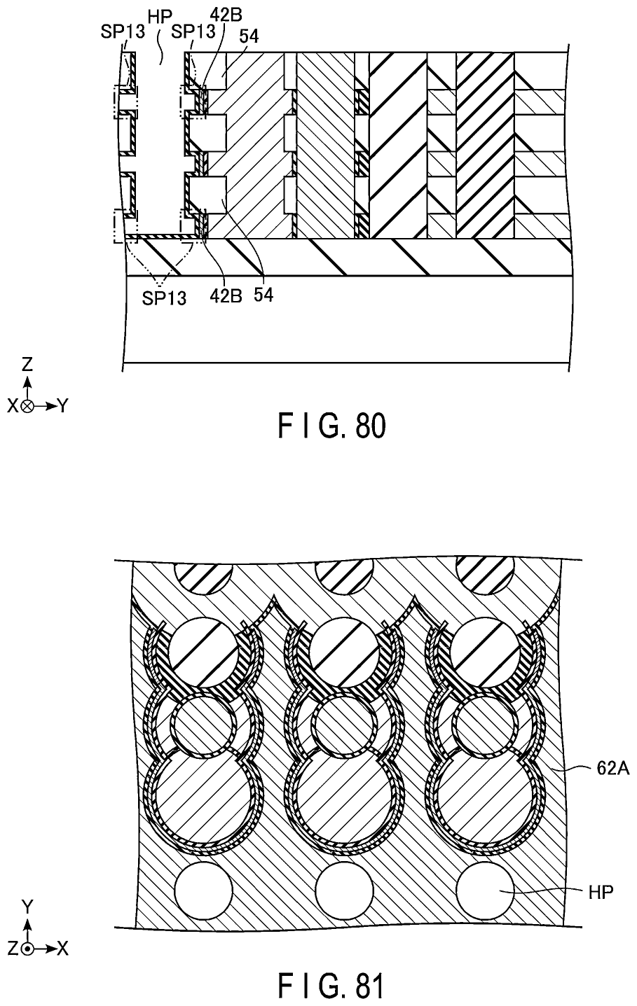

FIG. 76 illustrates a portion of the region illustrated in FIG. 3. FIG. 77 illustrates the region illustrated in FIG. 4. FIG. 78 illustrates the region illustrated in FIG. 5. FIG. 79 illustrates the region illustrated in FIG. 6. FIG. 80 illustrates the region illustrated in FIG. 7.

As illustrated in FIGS. 76 to 80, an insulator 61A is deposited. In one example, the insulator 61A includes silicon oxide. Examples of deposition methods include CVD. The insulator 61A covers the surfaces of the semiconductors 42B and 44, the conductor 46, and the insulator 54. The insulator 61A is thin. Therefore, in one example, the space SP13 is not filled with the insulator 61A.

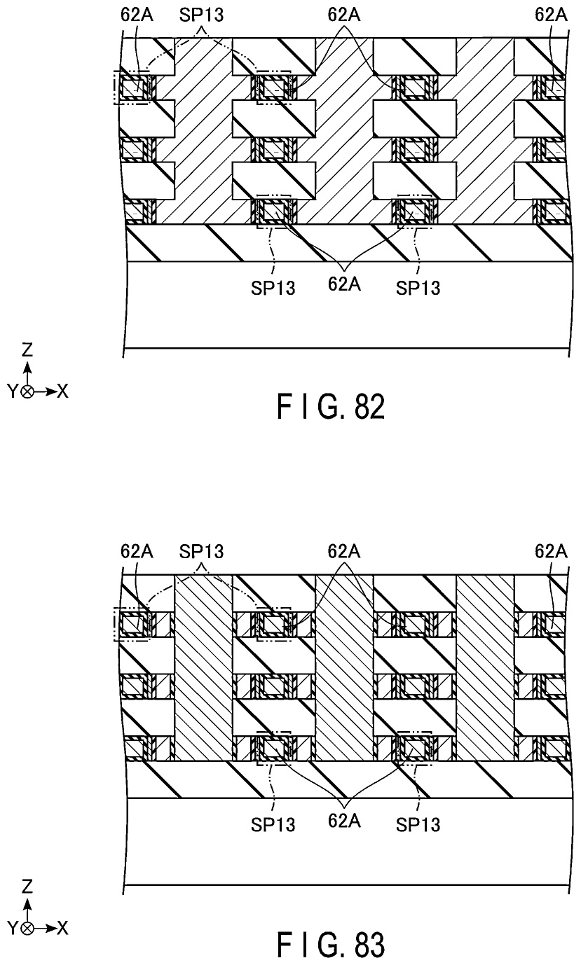

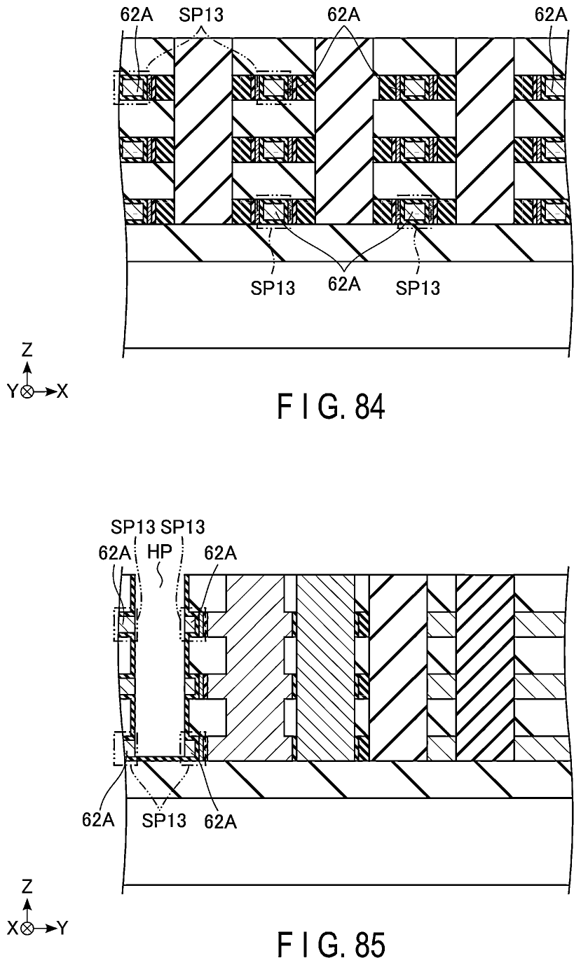

FIG. 81 illustrates a portion of the region illustrated in FIG. 3. FIG. 82 illustrates the region illustrated in FIG. 4. FIG. 83 illustrates the region illustrated in FIG. 5. FIG. 84 illustrates the region illustrated in FIG. 6. FIG. 85 illustrates the region illustrated in FIG. 7.

As illustrated in FIGS. 81 to 85, the conductor 62A is deposited in the space SP13. In one example, the conductor 62A contains titanium nitride. Examples of deposition methods include CVD. By the deposition, the space SP13 is filled with the conductor 62A.

The conductor 62A formed in the hole HP is removed in the process of forming the conductor 62A. Thus, the hole HP is formed again. In the hole HP, the conductor 62A is exposed.

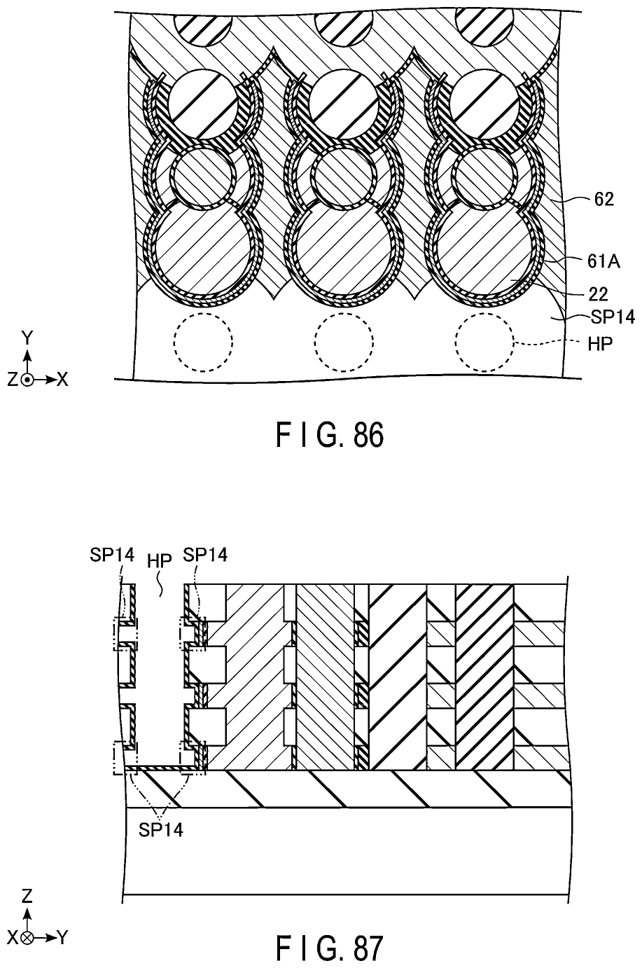

FIG. 86 illustrates a portion of the region illustrated in FIG. 3. FIG. 87 illustrates the region illustrated in FIG. 4.

As illustrated in FIGS. 86 and 87, portions of the conductor 62A exposed in the hole HP are removed. Examples of removal methods include wet etching. By the removal, a space SP14 is formed around the hole HP in the layer where the memory cell MC is located (the layer where the insulator 48A has been located). The space SP14 has a shape in which annular shapes surrounding the hole HP are combined. In the space SP14, portions of the insulator 61A along the lower end of the semiconductor 22 are exposed.

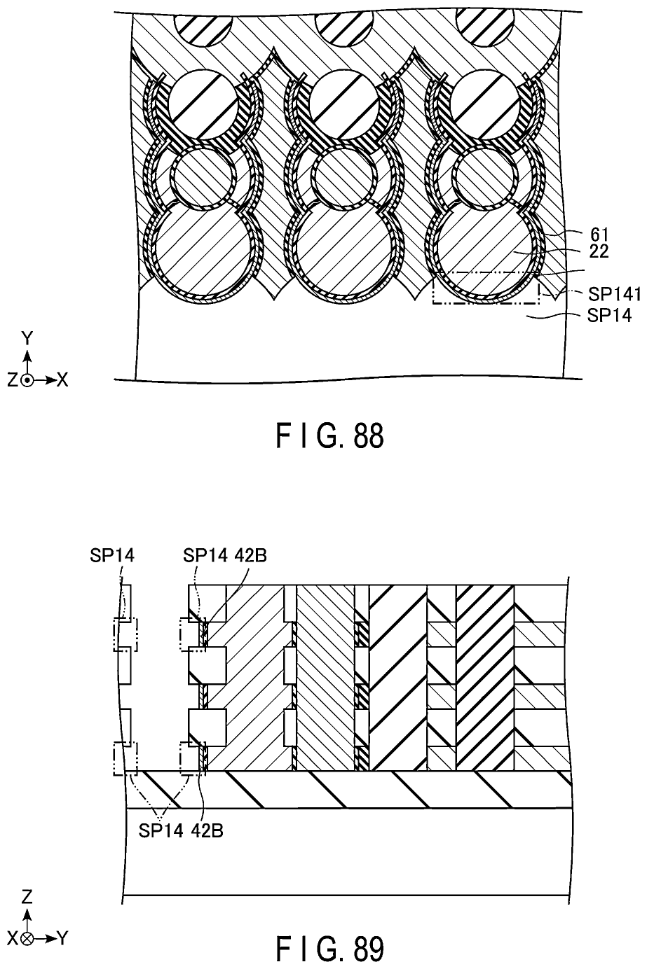

FIG. 88 illustrates a portion of the region illustrated in FIG. 3. FIG. 89 illustrates the region illustrated in FIG. 4.

As illustrated in FIGS. 88 and 89, portions of the insulator 61A exposed in the space SP14 and the hole HP are removed. Examples of removal methods include wet etching. By partial removal of the insulator 61A, the insulator 61A becomes the insulator 61. In the space SP14, the semiconductor 42B is exposed.

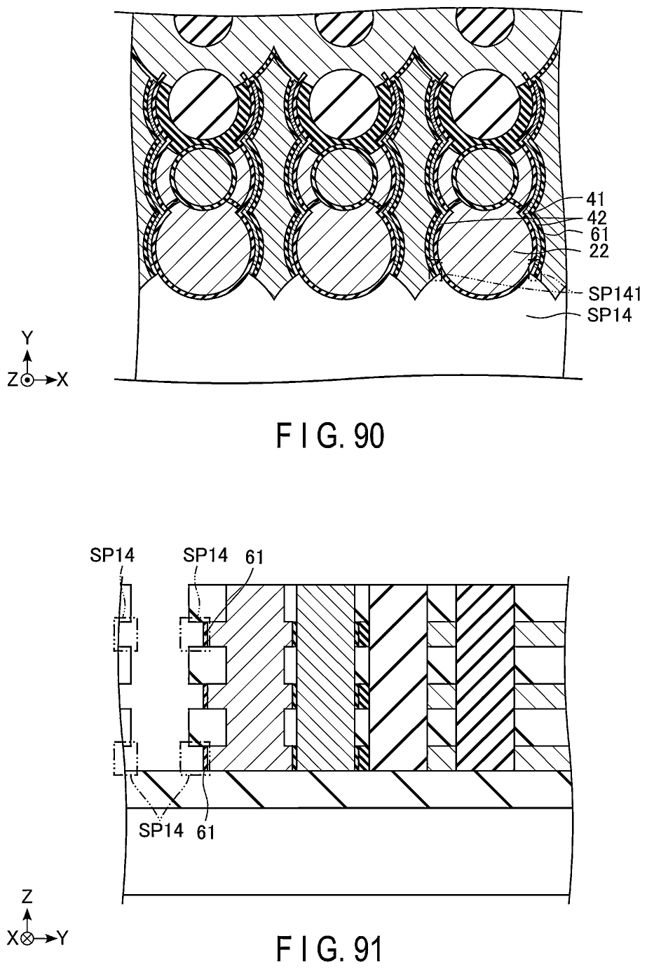

FIG. 90 illustrates a portion of the region illustrated in FIG. 3. FIG. 91 illustrates the region illustrated in FIG. 4.

As illustrated in FIGS. 90 and 91, portions of the semiconductor 42B exposed in the space SP14 are removed. Examples of removal methods include wet etching. By the removal, the space SP14 extends over a lower region of the portion of the semiconductor 42B in the semiconductor 22, and includes portions SP141. The portions SP141 are located between the insulator 41 and the insulator 61. By partial removal of the semiconductor 42B, the semiconductor 42B becomes the semiconductor 42. In the portions SP141, the insulator 61 is exposed.

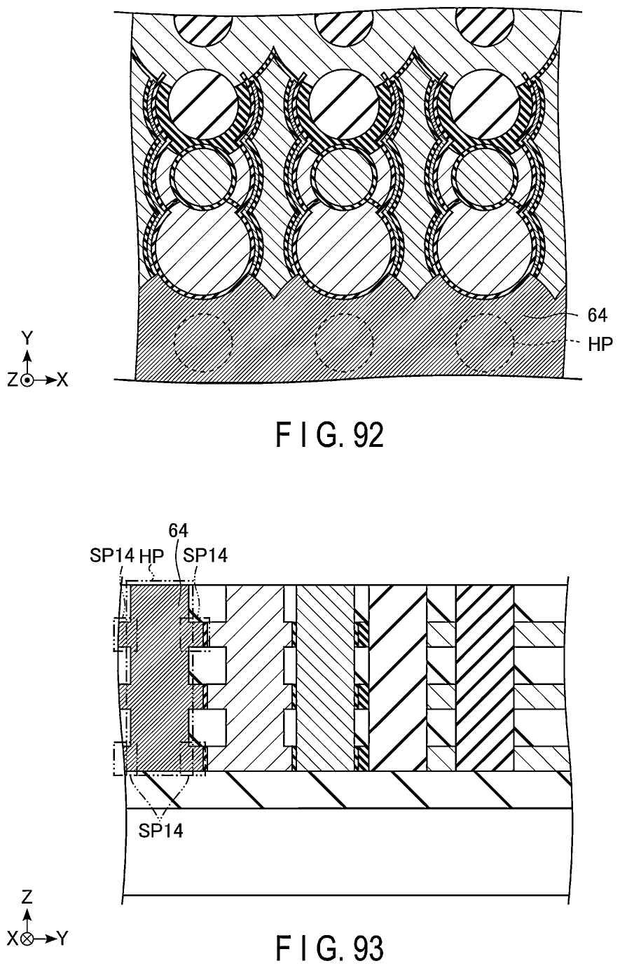

FIG. 92 illustrates a portion of the region illustrated in FIG. 3. FIG. 93 illustrates the region illustrated in FIG. 4.

As illustrated in FIGS. 92 and 93, the semiconductor 64 is deposited in the hole HP and the space SP14. In one example, the semiconductor 64 includes silicon. The semiconductor 64 is doped with impurities and has conductivity. In one example, the semiconductor 64 contains p-type impurities. Examples of the p-type impurities include boron. Examples of deposition methods include CVD.

The steps described above with reference to FIGS. 92 and 93 continue to the steps described above with reference to FIGS. 57 to 59.

According to the second modification, it is possible to suppress the influence of noise on each other by the memory cells MC adjacent along the xy plane.

### 1.3. Other Modifications

The transistors TrS and TrC may be n-type, and the transistor TrT may be p-type. In this example, the semiconductor 44 is doped with n-type impurities. Examples of the n-type impurities include phosphorus. Furthermore, the semiconductors 21, 22, and 24 can also be doped with n-type impurities instead of p-type impurities.

Instead of depositing the sacrificial material SM7 in the steps described above with reference to FIGS. 36 to 38, the conductor 38A may be deposited. In this case, the semiconductor 37 has the same shape as the sacrificial material SM7. The manufacturing step continues to the steps described above with reference to FIGS. 66 to 68.

The hole HP may be filled with metal instead of the semiconductor 21.

The two semiconductors 35 on both sides of the semiconductor 24 may be connected on the upper side of the semiconductor 24. In this structure, the semiconductor 37 surrounding the conductor 26 may be connected without an opening on the lower side of the conductor 26.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor memory device comprising:
a first interconnect extending along a first plane including a first axis and a second axis intersecting with the first axis, the first axis extending in a first direction;
a second interconnect extending along the first plane and provided in the first direction from the first interconnect;
a third interconnect extending along the first plane and provided in the first direction from the second interconnect;
a first conductor extending along the first plane and provided in the first direction from the second interconnect;
a first insulator surrounding the third interconnect along the first plane and having a portion located between the third interconnect and the second interconnect;
a first semiconductor sandwiching the first insulator together with the third interconnect;
a second insulator between the second interconnect and the first semiconductor;
a third insulator surrounding the first conductor along the first plane;
a second conductor in contact with the first semiconductor;
a second semiconductor sandwiching the third insulator together with the first conductor and being in contact with the second conductor;
a fourth insulator extending over the second interconnect, the first semiconductor, and the second semiconductor along the first plane;
a third semiconductor in contact with the first interconnect and including a portion sandwiching the fourth insulator together with the second interconnect and a portion sandwiching the fourth insulator together with the first semiconductor;
a fourth semiconductor in contact with the third semiconductor and sandwiching the fourth insulator together with the second semiconductor; and
a third conductor in contact with the fourth semiconductor.

2. The semiconductor memory device according to claim 1, wherein:
the fourth insulator covers a portion of the second interconnect facing the first interconnect.

3. The semiconductor memory device according to claim 1, wherein:
the first insulator covers a portion of the third interconnect facing the second interconnect.

4. The semiconductor memory device according to claim 1, wherein:
the second insulator covers a portion of the second interconnect facing the first semiconductor.

5. The semiconductor memory device according to claim 1, wherein:
the first insulator covers a portion of the third interconnect facing the first conductor.

6. The semiconductor memory device according to claim 1, wherein:
the third insulator covers a portion of the first conductor facing the third interconnect.

7. The semiconductor memory device according to claim 1, wherein:
the third insulator covers a portion of the first conductor facing the third conductor.

8. The semiconductor memory device according to claim 1, wherein:
the second interconnect includes a portion aligned with the third interconnect along the first axis.

9. The semiconductor memory device according to claim 1, wherein:
the first interconnect includes a portion aligned with the second interconnect along the first axis.

10. The semiconductor memory device according to claim 1, wherein:
the second interconnect, the third interconnect, and the first conductor are curved along the first plane.

11. The semiconductor memory device according to claim 10, wherein:
the third semiconductor includes a portion curved along the second interconnect, a portion curved along the third interconnect, and a portion curved along the first conductor.

12. The semiconductor memory device according to claim 10, wherein:
the first semiconductor is curved along the third interconnect.

13. The semiconductor memory device according to claim 10, wherein:
the second semiconductor includes a portion curved along the first conductor.

14. The semiconductor memory device according to claim 10, wherein:
the fourth semiconductor is curved along the first conductor.

15. The semiconductor memory device according to claim 1, further comprising:
a fifth insulator surrounding the first interconnect, the third semiconductor, the fourth semiconductor, and the third conductor along the first plane.

16. The semiconductor memory device according to claim 1, wherein:
a surface where the third semiconductor and the fourth semiconductor are in contact with each other is aligned with the first conductor along the first axis.

17. The semiconductor memory device according to claim 1, wherein:
a surface where the third semiconductor and the fourth semiconductor are in contact with each other is aligned with the third interconnect along the first axis.

18. The semiconductor memory device according to claim 1, further comprising:
a sixth insulator extending over a region on the first interconnect, a region on the third semiconductor, a region on the fourth semiconductor, and a region on the third conductor along the first plane.

19. The semiconductor memory device according to claim 18, further comprising:
a fourth conductor surrounding the sixth insulator along the first plane.
